(19) United States
(12) Patent Application Publication
(10) Pub. No.: US 2024/0315041 A1
(43) Pub. Date: Sep. 19, 2024

(54) SEMICONDUCTOR MEMORY DEVICE, AND SEMICONDUCTOR MEMORY DEVICE MANUFACTURING METHOD

(71) Applicant: Kioxia Corporation, Tokyo (JP)

(72) Inventors: Kiwamu SAKUMA, Yokkaichi Mie (JP); Takamasa HAMAI, Nagoya Aichi (JP); Yuuichi KAMIMUTA, Seoul (KR); Kunifumi SUZUKI, Yokkaichi Mie (JP)

(21) Appl. No.: 18/593,981

(22) Filed: Mar. 4, 2024

(30) Foreign Application Priority Data
Mar. 16, 2023 (JP) 2023-041972

(51) Int. Cl. H10B 51/20; H10B 51/30

(52) U.S. Cl. CPC H10B 51/20; H10B 51/30

(57) ABSTRACT

A semiconductor memory device has a stacked body in which a plurality of electrode layers and a plurality of insulating layers are alternately stacked in a first direction, an electrode film that extends in the stacked body in the first direction, and a plurality of ferroelectric films. Each of the ferroelectric films is disposed between and in contact with one of the electrode layers and the electrode film, and has a thickness in the first direction that is greater than the electrode layer that is in contact therewith.

### CROSS-REFERENCE TO RELATED APPLICATION(S)

This application is based upon and claims the benefit of priority from Japanese Patent Application No. 2023-041972, filed Mar. 16, 2023, the entire contents of which are incorporated herein by reference.

### FIELD

Embodiments described herein relate generally to a semiconductor memory device, and to a semiconductor memory device manufacturing method.

### BACKGROUND

A semiconductor memory device provided with a memory cell in which a ferroelectric film is used carries out an operation to write and erase data into and from the memory cell in accordance with an orientation of an electric field applied to the ferroelectric film. In such a semiconductor memory device, when the number of write-erase cycles increases, write-erase characteristics may deteriorate. Therefore, there is a demand for an increase in reliability of an operation including a write-erase in such a semiconductor memory device.

### DESCRIPTION OF THE DRAWINGS

FIG. 1 is a perspective view showing a configuration of a semiconductor memory device according to a first embodiment.

FIG. 2 is a block diagram showing a configuration of the semiconductor memory device according to the first embodiment.

FIG. 3 is a circuit diagram showing a configuration of a memory cell array in the first embodiment.

FIG. 4 is a sectional view showing a configuration of the memory cell array in the first embodiment.

FIG. 5 is a plan view showing a configuration of the memory cell array in the first embodiment.

FIGS. 6A to 6C are perspective views showing directions of crystal axes of a ferroelectric film in the first embodiment.

FIG. 7 is a diagram showing polarization characteristics of ferroelectric memory cells.

FIGS. 8A to 8C and 9A to 9C are sectional views showing a semiconductor memory device manufacturing method according to the first embodiment.

FIGS. 10A and 10B are perspective views showing a semiconductor memory device manufacturing method according to the first embodiment.

FIGS. 11A to 11C are sectional views showing a semiconductor memory device manufacturing method according to a modification of the first embodiment.

FIG. 12 is a perspective view showing a schematic configuration of a semiconductor memory device according to a second embodiment.

FIG. 13 is a sectional view showing a configuration of a memory cell array in the second embodiment.

FIG. 14 is a plan view showing a configuration of the memory cell array in the second embodiment.

FIG. 15 is a sectional view showing a configuration of a memory cell array in a third embodiment.

FIGS. 16A and 16B are sectional views showing a semiconductor memory device manufacturing method according to the third embodiment.

FIGS. 17A and 17B are sectional views showing an insulating layer recession amount in the third embodiment.

FIG. 18 is a diagram showing a relationship between the insulating layer recession amount and a memory cell operating voltage in the third embodiment.

FIG. 19 is a sectional view showing a configuration of a memory cell array in a fourth embodiment.

FIGS. 20A and 20B are sectional views showing a semiconductor memory device manufacturing method according to the fourth embodiment.

### DETAILED DESCRIPTION

Embodiments provide a semiconductor memory device having increased operational reliability and a method of manufacturing the same.

In general, according to one embodiment, a semiconductor memory device has a stacked body in which a plurality of electrode layers and a plurality of insulating layers are alternately stacked in a first direction, an electrode film that extends in the stacked body in the first direction, and a plurality of ferroelectric films. Each of the ferroelectric films is disposed between and in contact with one of the electrode layers and the electrode film, and has a thickness in the first direction that is greater than the electrode layer that is in contact therewith.

Hereafter, a semiconductor memory device according to embodiments will be described in detail, with reference to the attached drawings. The present disclosure is not limited by these embodiments.

### First Embodiment

A semiconductor memory device according to a first embodiment is provided with a memory cell in which a ferroelectric film is used, and a write-erase of data is carried out in accordance with an orientation of an electric field applied to the ferroelectric film, and measures for increasing reliability of an operation including a write-erase operation are implemented.

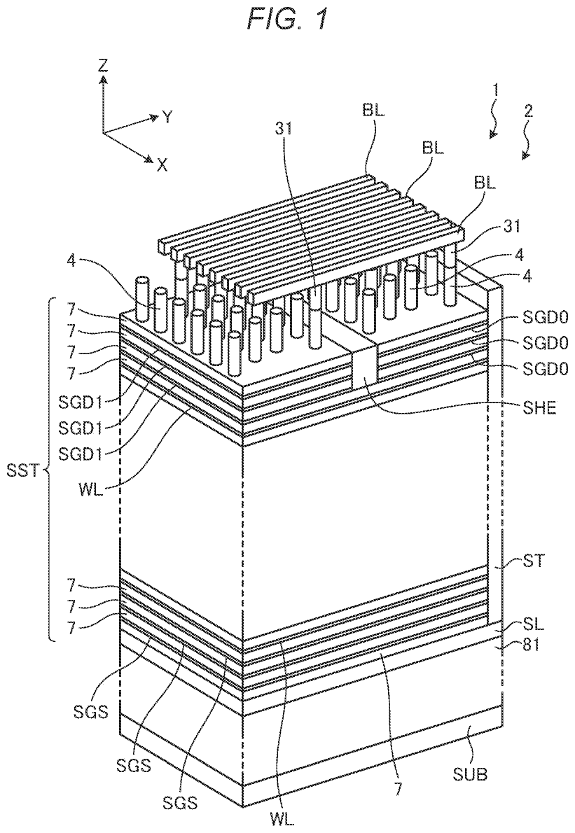

A semiconductor memory device 1 may be configured as shown in FIG. 1. FIG. 1 is a perspective view showing a configuration of the semiconductor memory device 1.

The semiconductor memory device 1 is a three-dimensional semiconductor memory, and is, for example, a ferroelectric memory. The semiconductor memory device 1 has a memory cell array 2, word lines WL, select gate lines SGD, select gate lines SGS, bit lines BL, and a source line SL. Hereafter, a direction in which the bit line BL extends is referred to as a Y direction, a direction in which memory cell transistors are stacked is referred to as a Z direction, and a direction perpendicular to the Y direction and the Z direction is referred to as an X direction.

Select gate lines SGS are stacked on a substrate SUB alternating with insulating layers 7. In the example of FIG. 1, three layers of select gate lines SGS are provided. In the example of FIG. 1, multiple layers of the word line WL are provided alternately with the insulating layer 7 in the Z direction above the select gate lines SGS. Select gate lines SGD are stacked alternately with the insulating layer 7 in the Z direction above the word lines WL. The select gate lines SGS, the word lines WL, and the select gate lines SGD are each of a plate-shape extending in the X direction and the Y direction.

In the example of FIG. 1, the select gate lines SGD, the word lines WL, and the select gate lines SGS are divided in the Y direction, and thereby isolated, by a slit ST. The source line SL is disposed on a +Z side of the substrate SUB above an interlayer insulating film 81. The slit ST is provided on a +Z side of the source line SL, and extends in the X direction and the Z direction.

The select gate lines SGD are, for example, divided in the Y direction by a dividing film SHE. Select gate lines SGD0 and select gate lines SGD1 that are separated in the Y direction are shown in the example of FIG. 1. The dividing film SHE is provided above (on a +Z side of) the word line WL, and extends in the X direction and the Z direction. Because of this, the select gate lines SGD0 and the select gate lines SGD1 are arranged in the Y direction above the word lines WL. In the example of FIG. 1, three layers alternately with the insulating layer 7 in the Z direction the select gate lines SGD0 and the select gate lines SGD1 are provided.

The substrate SUB is, for example, a silicon substrate. The select gate lines SGS, the word lines WL, and the select gate lines SGD may be formed of, for example, a material having a metal such as tungsten (W) as a main component. The insulating layers 7 and the interlayer insulating film 81 may be formed of, for example, an insulator such as silicon oxide.

The semiconductor memory device 1 further includes a multiple of columnar bodies 4. Each columnar body 4 penetrates the select gate lines SGS, the word lines WL, and the select gate lines SGD, and extends in the Z direction, which is a stacking direction of the select gate lines SGS, the word lines WL, and the select gate lines SGD. Multiple bit lines BL are provided above the select gate lines SGD.

Each columnar body 4 is electrically connected to a bit line BL via a corresponding contact plug 31. For example, one of the columnar bodies 4 that shares the select gate line SGD0 and one of the columnar bodies 4 that shares the select gate line SGD1 are electrically connected to one bit line BL. The columnar body 4 includes a columnar channel region.

In order to simplify an illustration, an interlayer insulating film provided between the select gate line SGD and the bit line BL is omitted from FIG. 1.

In the semiconductor memory device 1, each of the select gate lines SGD, the word lines WL, and the select gate lines SGS includes a conductive layer. A stacked body SST in which a plurality of conductive layers and a plurality of insulating layers are alternately stacked is configured on a +Z side of the source line SL. The columnar channel region of the columnar body 4 includes a semiconductor film. The stacked body SST is penetrated by the columnar body 4, and a three-dimensional memory cell array is formed with this structure.

That is, in the semiconductor memory device 1, a portion in which the word line WL and the columnar body 4 intersect functions as a memory cell, and the memory cell array 2 includes a multiple of such memory cells that are three-dimensionally arranged. Also, a portion in which the select gate line SGS and the columnar body 4 intersect functions as a source-side select gate, and a portion in which the select gate lines SGD0 and SGD1 and the columnar body 4 intersect function as drain-side select gates. A storage capacity of the semiconductor memory device 1 can be increased by increasing the number of word line WL layers stacked in the stacked body SST, and doing so does not require more precise patterning technology.

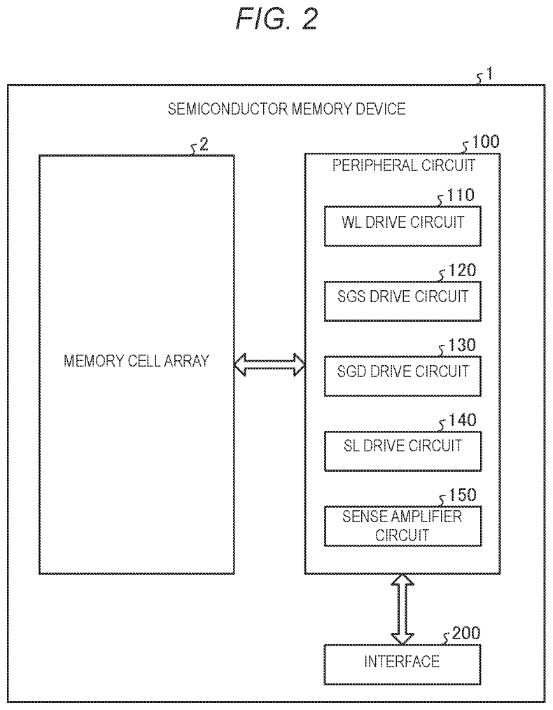

FIG. 2 is a block diagram showing a schematic configuration of the semiconductor memory device 1. As shown in FIG. 2, the semiconductor memory device 1 has the memory cell array 2, a peripheral circuit 100, and an interface 200. The peripheral circuit 100 includes a WL drive circuit 110, an SGS drive circuit 120, an SGD drive circuit 130, an SL drive circuit 140, and a sense amplifier circuit 150.

The WL drive circuit 110 is a circuit that controls a voltage applied to the word lines WL, and the SGS drive circuit 120 is a circuit that controls a voltage applied to the select gate lines SGS. The SGD drive circuit 130 is a circuit that controls a voltage applied to the select gate lines SGD, and the SL drive circuit 140 is a circuit that controls a voltage applied to the source line SL. The sense amplifier circuit 150 is a circuit that controls a voltage applied to the bit lines BL, and is a circuit that determines data read in accordance with a signal from a selected memory cell.

The peripheral circuit 100 controls an operation of the semiconductor memory device 1 based on an instruction input from an external device (for example, a memory controller of a memory system in which the semiconductor memory device 1 is implemented) via the interface 200.

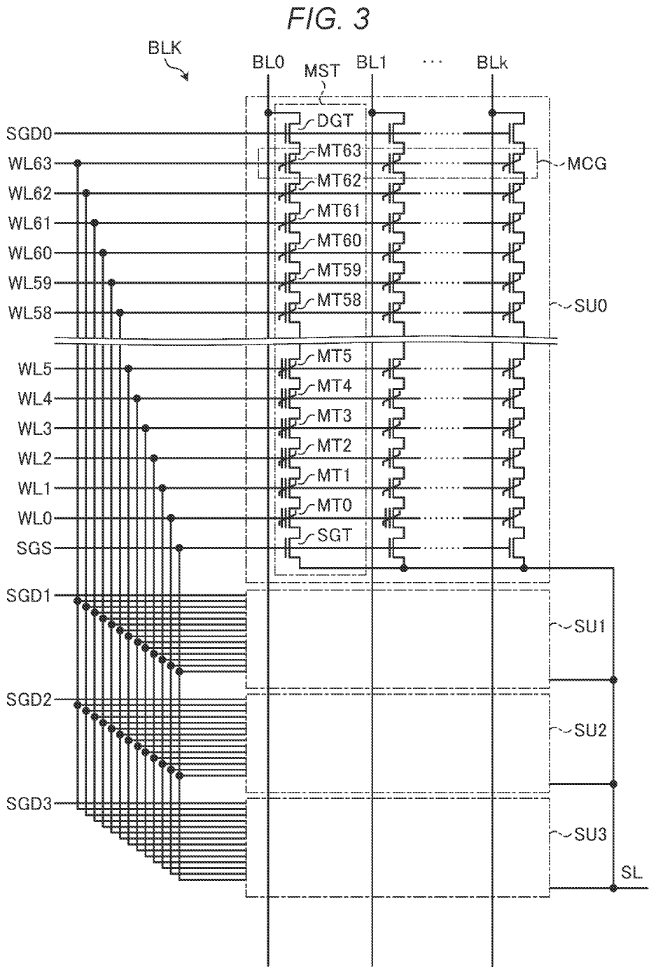

Next, a circuit configuration of the memory cell array 2 will be described, using FIG. 3. FIG. 3 is a circuit diagram showing a configuration of the memory cell array 2.

The memory cell array 2 has multiple blocks BLK, each of which is a group of memory cell transistors MT. Hereafter, the memory cell transistor MT will simply be called the memory cell MT.

Each block BLK has multiple string units SU0, SU1, SU2, and SU3, which are a group of memory cells MT corresponding to the word lines WL and the bit lines BL. Each block BLK includes, for example, 64 word lines WL0 to WL63 and k+1 bit lines BL0 to BLk, where k is any integer of 2 or greater.

Each string unit SU0 to SU3 has multiple memory strings MST, in which memory cells MT are connected in series. Four string units SU0 to SU3 are shown as an example in FIG. 3, but the number of string units may be two or less, or may be four or more. The number of memory strings MST in the string unit SU is not limited to any number.

The string units SU0, SU1, SU2, and SU3 respectively correspond to select gate lines SGD0, SGD1, SGD2, and SGD3, share the select gate line SGS, and are each driven as a unit in the block BLK. Each string unit SU may be driven by the corresponding select gate line SGD and the select gate line SGS. Also, each string unit SU includes multiple memory strings MST.

Each memory string MST has memory cells MT at location where columnar body 4 of the memory string intersect the word lines WL. For example, each memory string MST includes 64 memory cells MT (MT0 to MT63) and select transistors DGT and SGT.

The memory cell MT has a ferroelectric film between an electrode layer and an electrode film, and a write-erase of data may be carried out in accordance with an orientation of an electric field applied to the ferroelectric film via the electrode layer and the electrode film. The electrode layer corresponds to the word line WL, and the electrode film corresponds to a channel region connected to the bit line BL.

The 64 memory cells MT (MT0 to MT63) are connected in series between a source of the select transistor DGT and a drain of the select transistor SGT. The number of memory cells MT in the memory string MST is not limited to 64.

Gates of the select transistors DGT in the string units SU0 to SU3 are connected to the select gate lines SGD0 to SGD3 respectively. As opposed to this, gates of the select transistors SGT in each string unit SU are all connected to, for example, the select gate line SGS.

Drains of the select transistors DGT of the memory strings MST in each string unit SU are each connected to a different bit line of the bit lines BL0 to BLk. Also, the bit lines BL0 to BLk are each connected to one memory string MST in each string unit SU across the multiple blocks BLK. Furthermore, sources of each select transistor SGT are all connected to the source line SL.

That is, the string unit SU includes a group of memory strings MST that are connected to different bit lines BL0 to BLk, and are connected to the same select gate line SGD. Also, each block BLK is includes the multiple string units SU0 to SU3 that share the same word line WL. Further, the memory cell array 2 includes the multiple blocks BLK that share the same bit lines BL0 to BLk.

A group of memory cells MT that share the same word line WL is referred to herein as a “memory cell group MCG.” The memory cell group MCG is a minimum unit of a group of memory cells MT to which a predetermined voltage (for example, a write voltage or a read voltage) can be applied at one time via the word line WL.

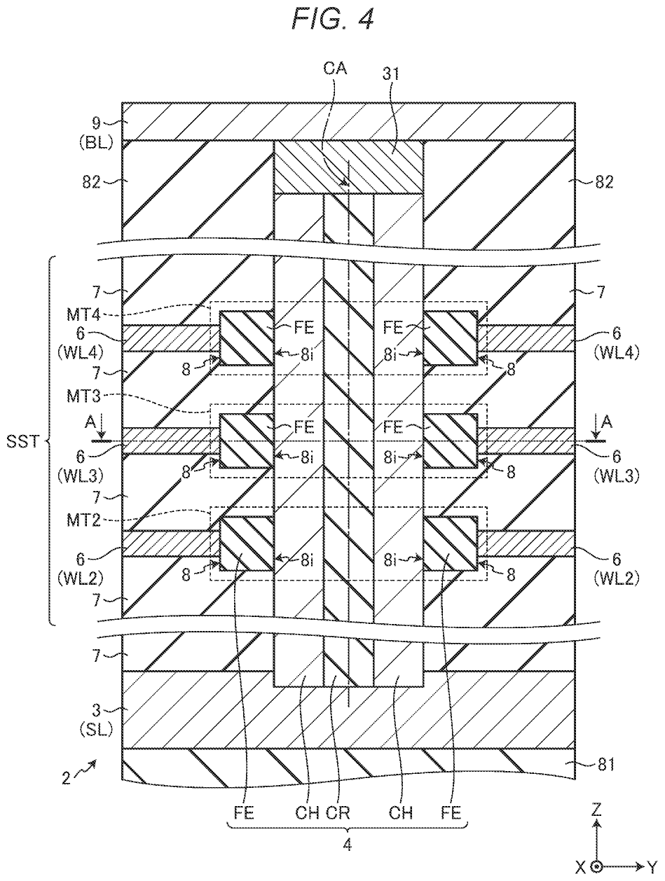

Next, a sectional configuration of the memory cell array 2 will be described, using FIG. 4. FIG. 4 is a sectional view showing a configuration of the memory cell array 2.

In the semiconductor memory device 1, a conductive layer 3 is disposed over the interlayer insulating film 81 on the +Z side of the substrate SUB. The conductive layer 3 may be formed of a material having a semiconductor (for example, silicon) including an impurity as a main component, or a material having a conductor (for example, a metal such as tungsten) as a main component. The conductive layer 3 extends in a plate-shape in the X and Y directions, and functions as the source line SL (refer to FIG. 1). The columnar bodies 4 are disposed on a +Z side of the conductive layer 3. One columnar body 4 is shown as an example in FIG. 4. The columnar bodies 4 are arranged in the X and Y directions. Each columnar body 4 extends in the Z direction inside the stacked body SST (refer to FIG. 1).

Each columnar body 4, having a substantially columnar shape that has a central axis CA in the Z direction, has, for example, an approximately cylindrical shape. Each columnar body 4 may have a tapered shape such that a diameter of a −Z side end is narrow in comparison with a diameter of a +Z side end. Each columnar body 4 may have a bow-shape such that a diameter of the −Z side end is narrow in comparison with a diameter of the +Z side end, and a diameter in a predetermined Z position between the +Z side end and the −Z side end is wider. For the sake of simplification, an approximately cylindrical shape is shown as an example of the shape of each columnar body 4 in FIG. 4.

Each columnar body 4 has multiple protruding portions on an outer side face thereof. The multiple protruding portions are arranged to be separated from each other in the Z direction. Each protruding portion has an approximate hollow disc shape centered on the central axis CA.

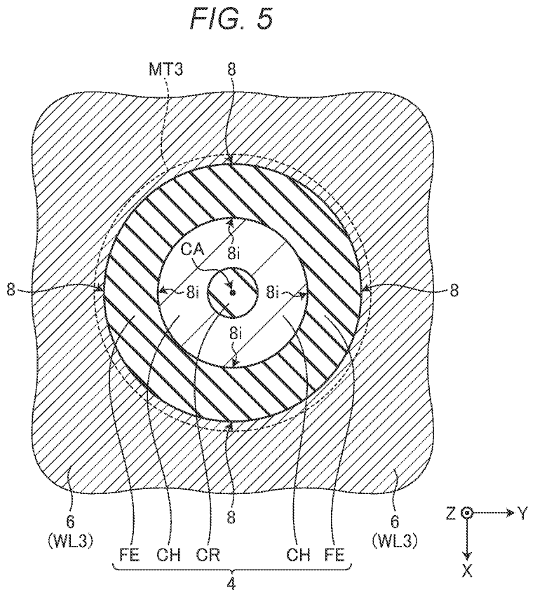

As shown in FIGS. 4 and 5, the columnar body 4 has, in order from the central axis CA side, a core member CR, a semiconductor film CH, and a ferroelectric film FE. FIG. 5 is an enlarged sectional view in the XY plane showing a configuration of the memory cell MT, and is an enlargement of the sectional view of a section cut along A-A line in FIG. 4.

The core member CR is disposed in a vicinity of the central axis CA of the columnar body 4, and has an approximately cylindrical shape that extends along the central axis CA of the columnar body 4. The core member CR may be formed of a material having an insulator (for example, a semiconductor oxide such as silicon oxide) as a main component.

The semiconductor film CH surrounds the core member CR from an outer side, and includes an approximately cylindrical shape that extends along the central axis CA of the columnar body 4. The semiconductor film CH may be formed of a material having a semiconductor (for example, polysilicon) that substantially includes no impurity (referred to herein as an undoped semiconductor), as a main component.

Multiple the ferroelectric films FE are disposed on an outer side face of the columnar body 4, forming the multiple protruding portions on the outer side face. The multiple ferroelectric films FE are arranged in the Z direction along the central axis CA, separated from each other in the Z direction. Each ferroelectric film FE is disposed in a Z position corresponding to a conductive layer 6. Each ferroelectric film FE surrounds the semiconductor film CH from an outer side, and has an approximate hollow disc shape including the central axis CA on an inner side. An inner side face 8i of the ferroelectric film FE faces the central axis CA. An outer side face 8 of the ferroelectric film FE faces a side opposite to that of the central axis CA.

The ferroelectric film FE may be formed of a material having a ferroelectric element as a main component. The ferroelectric film FE may be formed of a material having, for example, hafnium oxide (HfO) as a main component. The ferroelectric film FE may be formed of a material further including at least one element selected from a group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

The semiconductor film CH of the columnar body 4 is connected to the conductive layer 3 on a −Z side as the source line SL, and is connected on a +Z side via the contact plug 31 to a conductive layer 9 that functions as the bit line BL. That is, the semiconductor film CH makes up the channel region in the memory string MST.

The conductive layer 6 and the insulating layer 7 are alternately stacked repeatedly in the stacked body SST. Each conductive layer 6 extends in a plate shape in the X and Y directions. Each conductive layer 6 may be formed of a conductive material (for example, a metal such as tungsten) as a main component. Each insulating layer 7 extends in a plate shape in the X and Y directions. Each insulating layer 7 may be formed of a material having an insulator (for example, a semiconductor oxide such as silicon oxide) as a main component.

Although not shown in the drawings, the columnar body 4 may have a structure in which an insulating film is interposed between the semiconductor film CH and the ferroelectric film FE. Also, each conductive layer 6 may be such that a +Z side face, a −Z side face, and a face opposing the columnar body 4 are covered by an insulating film.

Of the multiple conductive layers 6 disposed separated from each other in the Z direction in the stacked body SST, the conductive layer farthest on the −Z side functions as the select gate line SGS, the conductive layer farthest on the +Z side functions as the select gate line SGD, and other conductive layers 6 include those that function as the word lines WL0 to WL63. The conductive layers 6 functioning as the word lines WL2 to WL4 are shown as examples in FIG. 4.

Although not shown in the drawings, the columnar body 4 may have an insulating film that is partially disposed at a location where the columnar body 4 intersects with the conductive layer 6 of the select gate line SGS, and an insulating film that is partially disposed at a location where the columnar body 4 intersects with the conductive layer 6 of the select gate line SGD.

The select transistor SGT (refer to FIG. 3) is formed at a location where the conductive layer 6 of the select gate line SGS intersects the semiconductor film CH. An insulating film interposed between the conductive layer 6 of the select gate line SGS and the semiconductor film CH functions as a gate insulating film. The memory cell MT0 (refer to FIG. 3) is formed at a location where the conductive layer 6 of the word line WL0 intersects the semiconductor film CH and a charge storage film CT. The memory cell MT1 is formed at a location where the conductive layer 6 of the word line WL1 intersects the semiconductor film CH. The memory cell MT2 is formed at a location where the conductive layer 6 of the word line WL2 intersects the semiconductor film CH. The memory cell MT3 is formed at a location where the conductive layer 6 of the word line WL3 intersects the semiconductor film CH. The memory cell MT4 is formed at a location where the conductive layer 6 of the word line WL4 intersects the semiconductor film CH. The select transistor DGT (refer to FIG. 3) is formed at a location where the conductive layer 6 of the select gate line SGD intersects the semiconductor film CH. An insulating film interposed between the conductive layer 6 of the select gate line SGD and the semiconductor film CH acts as a gate insulating film.

Herein, each ferroelectric film FE includes an approximate hollow disc shape, and a voltage E is applied in a direction from the semiconductor film CH toward the conductive layer 6, or a direction from the conductive layer 6 toward the semiconductor film CH. A polarized charge may be generated on the inner side face 8i and the outer side face 8 of the ferroelectric film FE. That is, a direction in which the voltage E is applied, which is a direction in the XY plane, is a radial direction in the XY plane from the central axis CA, or a direction opposite thereto. In a YZ cross-section that passes through the central axis CA shown as an example in FIG. 4, the direction in which the voltage E is applied is the Y direction.

Each ferroelectric film FE may be of a polycrystalline form. A crystal exhibiting ferroelectricity and a crystal exhibiting antiferroelectricity may be mixed in the ferroelectric film FE. For example, the ferroelectric film FE includes a plurality of crystals, each of which is an orthorhombic crystal. Each crystal has three crystal axes (an a axis, a b axis, and a c axis). Of the three crystal axes, the b axis is shorter than the a axis. The c axis is shorter than the a axis and longer than the b axis. The c axis functions as a polarizing axis.

Whether a crystal exhibits ferroelectricity or exhibits antiferroelectricity depends on the direction in which the voltage E is applied to the ferroelectric film FE and a direction in which the crystal is oriented in the ferroelectric film FE. When a crystal is oriented in such a way that the c axis intersects the direction in which the voltage E is applied, the crystal tends to exhibit antiferroelectricity. When a crystal is oriented in such a way that the c axis follows the direction in which the voltage E is applied (for example, in such a way that the c axis is parallel to the direction in which the voltage E is applied), the crystal tends to exhibit ferroelectricity.

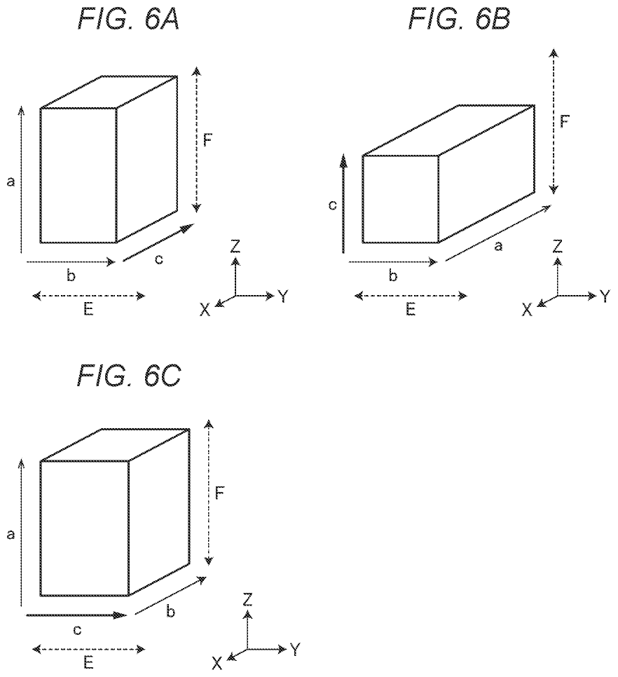

For example, a direction in which a crystal shown in FIG. 6A is oriented is such that the c axis intersects the direction in which the voltage E is applied. FIGS. 6A to 6C are perspective views showing directions of the crystal axes of the ferroelectric film FE. The crystal shown in FIG. 6A exhibits antiferroelectricity. The a axis is approximately parallel to the stacking direction (the Z direction), the b axis is approximately parallel to the direction in which the voltage E is applied in a planar direction (the X and Y directions), and the c axis is approximately perpendicular to the direction in which the voltage E is applied in the planar direction (the X and Y directions). In the YZ cross-section passing through the central axis CA (refer to FIG. 4), the a axis is approximately parallel to the Z direction, the b axis is approximately parallel to the Y direction, and the c axis is approximately parallel to the X direction.

A direction in which a crystal shown in FIG. 6B is oriented is such that the c axis intersects the direction in which the voltage E is applied. The crystal exhibits antiferroelectricity. The c axis is approximately parallel to the stacking direction (the Z direction), and is approximately perpendicular to the direction in which the voltage E is applied. The b axis is approximately parallel to the direction in which the voltage E is applied in the planar direction (the X and Y directions), and the a axis is approximately perpendicular to the direction in which the voltage E is applied in the planar direction (the X and Y directions). In the YZ cross-section passing through the central axis CA (refer to FIG. 4), the a axis is approximately parallel to the X direction, the b axis is approximately parallel to the Y direction, and the c axis is approximately parallel to the Z direction.

Meanwhile, a direction in which a crystal shown in FIG. 6C is oriented is such that the c axis follows the direction in which the voltage E is applied. The crystal exhibits ferroelectricity. The a axis is approximately parallel to the stacking direction (the Z direction), the c axis is approximately parallel to the direction in which the voltage E is applied in the planar direction (the X and Y directions), and the b axis is approximately perpendicular to the direction in which the voltage E is applied in the planar direction (the X and Y directions). In the YZ cross-section passing through the central axis CA (refer to FIG. 4), the a axis is approximately parallel to the Z direction, the b axis is approximately parallel to the X direction, and the c axis is approximately parallel to the Y direction.

When a percentage of crystals exhibiting antiferroelectricity is high in the ferroelectric film FE of each memory cell MT, spontaneous polarization is unlikely, and a polarized charge amount is difficult to secure. As a result, writing data into the memory cell MT becomes difficult. When a percentage of crystals exhibiting ferroelectricity is high, spontaneous polarization is likely, and a polarized charge amount is easy to secure. As a result, writing data into the memory cell MT becomes easy.

In each memory cell MT, the conductive layer 6 functions as a gate electrode, the semiconductor film CH functions as a channel region, and the ferroelectric film FE functions as a two-terminal element that can generate a polarized charge in each of an interface in contact with the conductive layer 6 and an interface in contact with the semiconductor film CH.

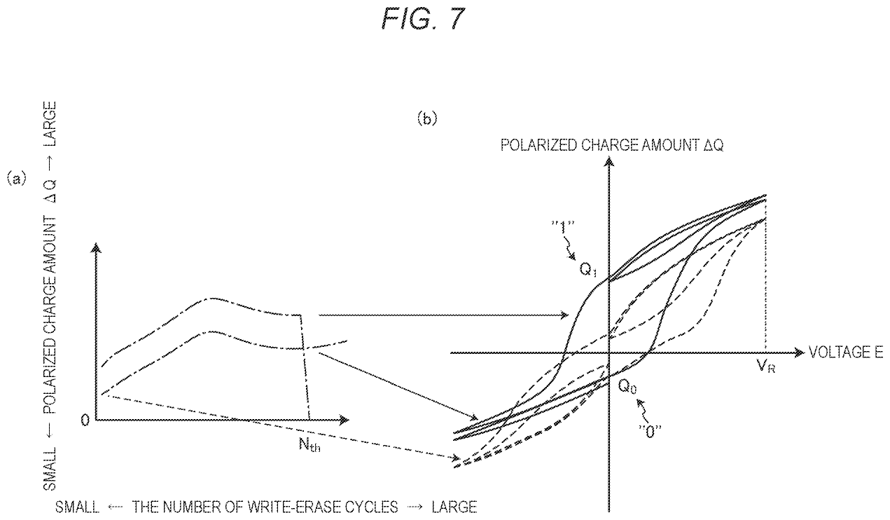

For example, when an electric field is applied to the ferroelectric film FE so that the conductive layer 6 becomes positive with respect to the semiconductor film CH (E>0), Vth is shifted in a negative direction and this corresponds to a write of “1” into the memory cell MT. “1” may be written into the memory cell MT. When spontaneous polarization is likely in the memory cell MT, “1” may be held in the memory cell MT. For example, when the memory cell MT exhibits ferroelectricity like that indicated by a solid line in (b) of FIG. 7, the ferroelectric film FE holds the polarized charge amount ΔQ=Q₁ (>0) of positive polarity in a vicinity of the side face 8i thereof in a state in which an application of the voltage E to the ferroelectric film FE is stopped. The polarized charge amount ΔQ=Q₁ corresponds to a bit value “1”.

When an electric field is applied to the ferroelectric film FE so that the conductive layer 6 becomes negative with respect to the semiconductor film CH (E<0), Vth is shifted in a positive direction and this corresponds to erasure of the “1” data from the memory cell MT. When spontaneous polarization is likely in the memory cell MT, “0” may be held in the memory call MT. For example, when the memory cell MT exhibits ferroelectricity like that indicated by a solid line in (b) of FIG. 7, the ferroelectric film FE holds the polarized charge amount ΔQ=Q₀ (<0) of negative polarity in a vicinity of the side face 8i thereof in a state in which an application of the voltage E to the ferroelectric film FE is stopped. The polarized charge amount ΔQ=Q₀ corresponds to a bit value “0”.

In each memory cell MT, when the percentage of crystals exhibiting ferroelectricity in the ferroelectric film FE is high in an initial state, endurance properties tend to be poor. Conversely, when the percentage of crystals exhibiting antiferroelectricity in the ferroelectric film FE is high in an initial state, endurance properties tend to be good.

For example, (a) of FIG. 7 shows a change in the polarized charge amount ΔQ accompanying the number of write-erase cycles of the memory cell MT. In (a) of FIG. 7, a vertical axis indicates the polarized charge amount ΔQ in a state in which “1” is written and an application of the voltage E is stopped, and indicates that the greater the polarized charge amount ΔQ, the better the write properties. A horizontal axis indicates the number of write-erase cycles.

When the percentage of crystals exhibiting ferroelectricity in the ferroelectric film FE is high in the initial state, as indicated by a dash-dot line in (a) of FIG. 7, the ferroelectric film FE exhibits ferroelectricity as a whole. From the initial state, the memory cell MT easily holds the polarized charge amount ΔQ in a state in which an application of the voltage E is stopped, as indicated by a solid line in (b) of FIG. 7, and writing data into the memory cell MT becomes easy. In this case, a write-erase operation with respect to the memory cell MT is repeatedly carried out, and when the number of write-erase cycles reaches a predetermined number N, the polarized charge amount ΔQ when the voltage E is not applied decreases sharply, as shown in (a) of FIG. 7, and write properties of the memory cell MT deteriorate sharply.

The ferroelectric film FE of the embodiments is configured in such a way that the percentage of crystals exhibiting antiferroelectricity in the ferroelectric film FE in the initial state is high, as indicated by another dot-dash line in (a) of FIG. 7. The ferroelectric film FE exhibits antiferroelectricity as a whole. In the memory cell MT, the polarized charge amount ΔQ when the voltage E is not applied is small in the initial state, as indicated by a dotted line in (b) of FIG. 7, and writing data into the memory cell MT becomes difficult.

When a write-erase operation with respect to the memory cell MT is repeatedly carried out from this state, the percentage of crystals exhibiting ferroelectricity in the ferroelectric film FE increases, and the ferroelectric film FE generally exhibits ferroelectricity as a whole. In the memory cell MT, the polarized charge of the ferroelectric film FE remains in a state in which an application of the voltage to the ferroelectric film FE is stopped, as indicated by a solid line in (b) of FIG. 7. The ferroelectric film FE shifting from a state of generally exhibiting antiferroelectricity to a state of generally exhibiting ferroelectricity in accordance with an increase in the number of write-erases is called a wake-up. Because of the wake-up, the polarized charge amount ΔQ in the memory cell MT is easily secured in a state in which an application of the voltage E is stopped, and writing data into the memory cell MT becomes easy.

Even when a write-erase operation with respect to the memory cell MT is repeatedly carried out, and the number of write-erase cycles reaches the predetermined number N, as indicated by a two dot-dash line in (a) of FIG. 7, write properties of the memory cell MT may be kept comparatively good.

Herein, the memory cell MT is provided at a location where the conductive layer 6 and the semiconductor film CH in the stacked body SST intersect across the ferroelectric film FE, as shown in FIGS. 1, 4, and 5. A thickness in the stacking direction (the Z direction) of the ferroelectric film FE at the intersection position is greater than a thickness in the stacking direction of the conductive layer 6. As will be described hereafter, this structure is manufactured under crystal orientation control that increases the percentage of crystals exhibiting antiferroelectricity, and is a structure in which the percentage of crystals exhibiting antiferroelectricity in the ferroelectric film FE increases in the initial state. A structure in which the percentage of crystals exhibiting antiferroelectricity in the ferroelectric film FE increases in the initial state can suppress a deterioration in write properties corresponding to an increase in the number of write-erase cycles in comparison with a structure in which the percentage of crystals exhibiting ferroelectricity in the ferroelectric film FE increases in the initial state (refer to (a) and (b) of FIG. 7), so that endurance properties can be improved.

That is, a structure that can increase an operational reliability of the semiconductor memory device 1 is a structure in which the thickness of the ferroelectric film FE in the stacking direction is greater than the thickness of the conductive layer 6 in the stacking direction at the intersection position where the memory cell MT is provided.

Also, as shown in FIG. 4, the side face 8 on the conductive layer 6 side of the ferroelectric film FE is flat in the stacking direction (the Z direction). The side face 8i on the semiconductor film CH side of the ferroelectric film FE is also flat in the stacking direction (the Z direction). With this structure, when the voltage E is applied in a direction from the semiconductor film CH toward the conductive layer 6, or in a direction from the conductive layer 6 toward the semiconductor film CH, an electric field concentration on the side faces 8 and 8i can be is less likely to develop, and a comparatively uniform electric field can be applied to the ferroelectric film FE. Because of this, a polarized charge can be efficiently generated on the inner side face 8i and the outer side face 8 of the ferroelectric film FE. As a result, the operational reliability of the semiconductor memory device 1 can be increased.

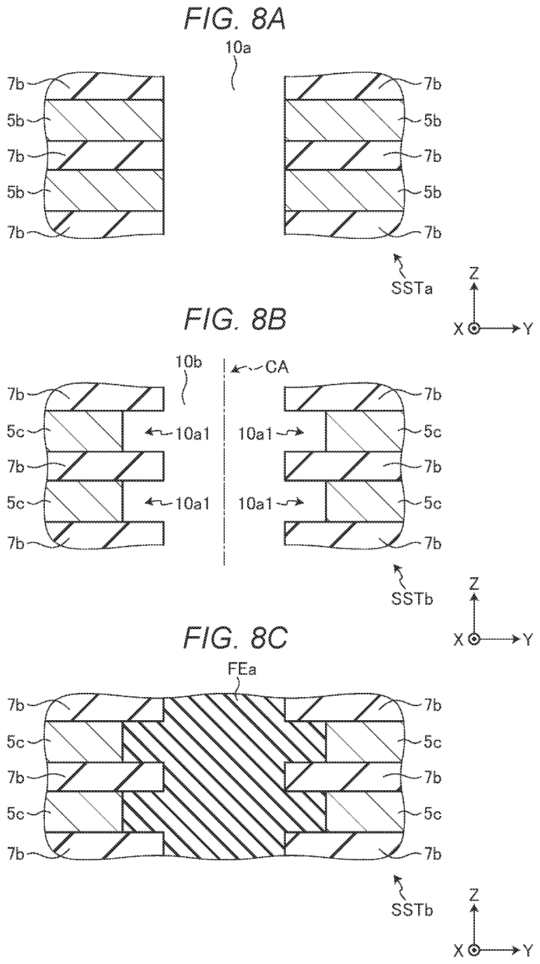

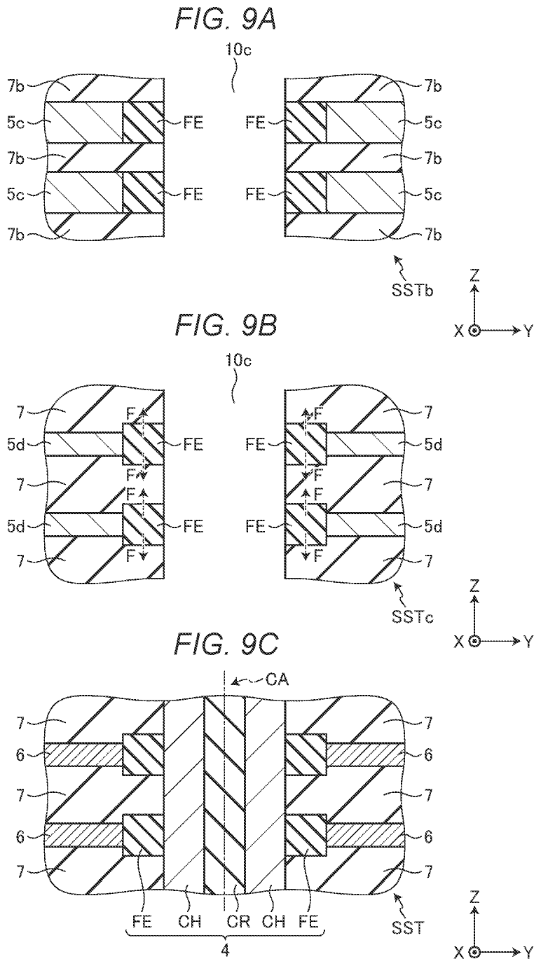

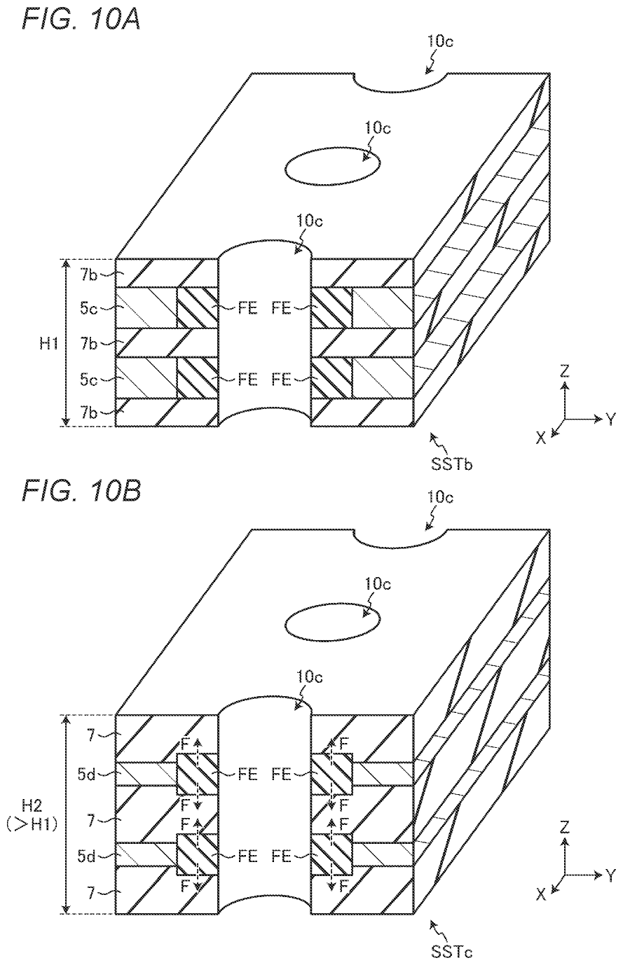

Next, a method of manufacturing the semiconductor memory device 1 will be described, using FIGS. 8A to 8C, 9A to 9C, and 10A to 10B. FIGS. 8A to 8C and FIGS. 9A to 9C are sectional views showing a method of manufacturing the semiconductor memory device 1. FIGS. 10A and 10B are perspective views showing a method of manufacturing the semiconductor memory device 1.

Prior to the process shown in FIG. 8A, a transistor is formed on the substrate SUB (refer to FIG. 1). In addition, a contact plug, a wiring film, a via plug, and the like are formed on the substrate SUB, and an interlayer insulating film is formed in a periphery of the contact plug, the wiring film, the via plug, and the like. By doing so, the peripheral circuit 100 (refer to FIG. 2) is formed. Subsequently, the interlayer insulating film 81 is deposited on the +Z side of the substrate SUB. The interlayer insulating film 81 (refer to FIG. 1) may be formed of a material having an insulator (for example, a semiconductor oxide such as silicon oxide) as a main component. The conductive layer 3 (refer to FIG. 4) is deposited on the +Z side of the interlayer insulating film 81. The conductive layer 3 may be formed of a material having a semiconductor (for example, silicon) including an impurity as a main component or a material having a conductor (for example, a metal such as tungsten) as a main component. A stacked body SSTa, partially shown in FIGS. 8A-8C, is formed by an insulating layer 7a and a semiconductor layer 5a being alternately deposited multiple times on the +Z side of the conductive layer 3. The insulating layer 7a may be formed of a material having a semiconductor oxide (for example, silicon oxide) as a main component. The semiconductor layer 5a may be formed of a material having a semiconductor (for example, amorphous silicon) as a main component. Each insulating layer 7a and each semiconductor layer 5a may be deposited to have substantially the same film thickness.

A resist pattern in which a position in which a memory hole 10a is to be formed is opened is formed on the uppermost insulating layer 7a of each stacked body SSTa. An anisotropic etching such as a reactive ion etching (RIE) is carried out with the resist pattern as a mask, whereby the memory hole 10a, which penetrates the stacked body SSTa and reaches the conductive layer 3, is formed.

In a process shown in FIG. 8B, a semiconductor layer recessing process is carried out, causing a side face of the semiconductor layer 5b exposed in the memory hole 10a to recede by etching. A recessed portion 10al is formed in an inner side face of a memory hole 10b by the semiconductor layer recessing process. The recessed portion 10al is formed in a Z position of a semiconductor layer 5c in a stacked body SSTa in such a way as to be recessed from the inner side face of the memory hole 10b in a direction away from the central axis CA of the memory hole 10b. For example, wet etching is carried out on the inner side face of the memory hole 10b using an etchant such that an etch selectivity of the semiconductor layer 5c with respect to that of the insulating layer 7b is high. Alternatively, dry etching is carried out on the inner side face of the memory hole 10b under conditions of an isotropic etching using a processing gas such that an etch selectivity of the semiconductor layer 5c with respect to that of the insulating layer 7b is high. By doing so, a side face of the semiconductor layer 5c exposed in the memory hole 10b is caused to recede by etching, whereby the recessed portion 10al can be formed in the inner side face of the memory hole 10b. A width of recession (an amount of recession) of the recessed portion 10al with respect to the inner side face of the memory hole 10b may be regulated by the etching time. A width in the Z direction of the recessed portion 10al is approximately equivalent to a film thickness of the semiconductor layer 5c.

In a process shown in FIG. 8C, a ferroelectric film FEa is deposited on a side face and a bottom face of the memory hole 10b. The ferroelectric film FEa is deposited in an amorphous state. At this time, the ferroelectric film FEa is embedded in the recessed portion 10al. The ferroelectric film FEa may be formed of a material having a ferroelectric body as a main component.

The ferroelectric film FEa may be formed of a material having, for example, hafnium oxide (HfO) as a main component. The ferroelectric film FEa may be formed of a material further including at least one element selected from a group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

In a process shown in FIGS. 9A and 10A, a resist pattern is formed on the uppermost (the farthest to the +Z side) insulating layer 7b of each stacked body SSTb at a position in which a memory hole 10c is to be formed. An anisotropic etching such as a reactive ion etching (RIE) is carried out with the resist pattern as a mask, whereby the memory hole 10c, which penetrates the stacked body SSTb and reaches the conductive layer 3, is formed. By doing so, a portion of the ferroelectric film FEa corresponding to the memory hole 10c is removed, while leaving a portion of the ferroelectric film FEa embedded in the recessed portion 10al as the ferroelectric film FE.

In a process shown in FIGS. 9B and 10B, a stacked body SSTc is thermally oxidized. By doing so, the ferroelectric film FE in the amorphous state is crystallized, changing to a polycrystalline state. Together with this, a portion of the semiconductor layer 5c in a vicinity of a face in contact with the insulating layer 7b is oxidized, whereby a semiconductor layer 5d is thinned and crystallized, together with which the insulating layer 7 is thickened.

At this time, each insulating layer 7 expands in the Z direction, as shown in FIG. 10B. For example, a height of a stacked body in a case of three insulating layers 7 expands from H1 shown in FIG. 10A to H2 shown in FIG. 10B (H2>H1). Because of this, a tensile force Fin the Z direction acts on each ferroelectric film FE, as shown by a dotted arrow in FIGS. 9B and 10B. The tensile force F includes stress such that the insulating layer 7 on the +Z side of the ferroelectric film FE pulls the ferroelectric film FE to the +Z side, or stress such that the insulating layer 7 on the −Z side of the ferroelectric film FE pulls the ferroelectric film FE to the −Z side.

Immediately after being crystallized, a direction of orientation of the multiple of crystals in the ferroelectric film FE is random. As a result of the tensile force F applied to the ferroelectric film FE, a percentage of crystals whose direction of orientation is such that the a axis, which is the longest of the multiple of crystal axes (the a axis, the b axis, and the c axis), follows the direction of the tensile force F may increase. As a result, the percentage of crystals with the direction of orientation of FIGS. 6A and 6C may increase in comparison with the percentage of crystals with the direction of orientation of FIG. 6B. The percentage of crystals with the direction of orientation of FIG. 6A and the percentage of crystals with the direction of orientation of FIG. 6C may be the same. Because of this, the percentage of crystals with the direction of orientation of FIG. 6A or FIG. 6C increases in the ferroelectric film FE, and the ferroelectric film FE exhibits antiferroelectricity as a whole.

In a process shown in FIG. 9C, the semiconductor layer 5d of the stacked body SSTc is removed. The conductive layer 6 is embedded in a gap formed by the removal. The conductive layer 6 may be formed of a material having a conductor (for example, a metal such as tungsten) as a main component. Because of this, the semiconductor layer 5d is replaced by the conductive layer 6, and the stacked body SST in which the conductive layer 6 and the insulating layer 7 are alternately stacked repeatedly is formed.

A semiconductor is then deposited on a side face and a bottom face of the memory hole 10c, to form the semiconductor film CH. The semiconductor film CH may be formed of a material having a semiconductor (for example, polysilicon) that substantially includes no impurity, as a main component. Further, the core member CR Is embedded in the remaining portion of the memory hole 10c. The core member CR may be formed of an insulator such as silicon oxide. Because of this, the core member CR, the semiconductor film CH, and the multiple of ferroelectric films FE are disposed in concentric circle form with respect to the central axis CA, whereby the columnar body 4 that penetrates the stacked body SST in the Z direction is formed.

In this way, the semiconductor memory device 1 shown in FIGS. 1 to 5 can be manufactured using the manufacturing method shown in FIGS. 8A to 10B.

In the first embodiment, as heretofore described, in the semiconductor memory device 1, the memory cell MT is provided at a location where the conductive layer 6 and the semiconductor film CH in the stacked body SST intersect across the ferroelectric film FE. The thickness of the ferroelectric film FE in the stacking direction at the intersection position is greater than the thickness of the conductive layer 6 in the stacking direction. This structure is manufactured under crystal orientation control such that the Z direction tensile force Facts on the ferroelectric film FE, and is a structure in which the percentage of crystals exhibiting antiferroelectricity in the ferroelectric film FE increases in the initial state. That is, an increase in the operational reliability of the semiconductor memory device 1 can be provided using a structure in which the thickness of the ferroelectric film FE in the stacking direction at an intersection position where the memory cell MT is provided, is greater than the thickness of the conductive layer 6 in the stacking direction.

Also, in the semiconductor memory device 1 of the first embodiment, the side face 8 on the conductive layer 6 side of the ferroelectric film FE is flat in the stacking direction, and the side face 8i on the semiconductor film CH side of the ferroelectric film FE is flat in the stacking direction. With this structure, when the voltage E is applied in a direction from the semiconductor film CH toward the conductive layer 6, or in a direction from the conductive layer 6 toward the semiconductor film CH, an electric field concentration on the side faces 8 and 8i is less likely to develop, and a comparatively uniform electric field can be applied to the ferroelectric film FE. Because of this, a polarized charge can be efficiently generated on the inner side face 8i and the outer side face 8 of the ferroelectric film FE. As a result, the operational reliability of the semiconductor memory device 1 can be increased.

Each columnar body 4 may have a configuration in which the core member CR is omitted.

Also, in the manufacturing method, the semiconductor layer 5d is replaced by the conductive layer 6 as shown in FIGS. 8A to 10B, but the semiconductor layer 5d may be conductive, in which case it can function as a word line and do not need to be replaced. In such a case, the semiconductor layer 5d may be formed of a semiconductor material that includes an impurity and to which conductivity is imparted (for example, an n-type polysilicon including a donor impurity or a p-type polysilicon including an acceptor impurity) as a main component in the process shown in FIG. 8A. Also, the removal of the semiconductor layer 5d and the embedding of the conductive layer 6 would be omitted from the process shown in FIG. 9C. Other points are the same as in the manufacturing method shown in FIGS. 8A to 10B.

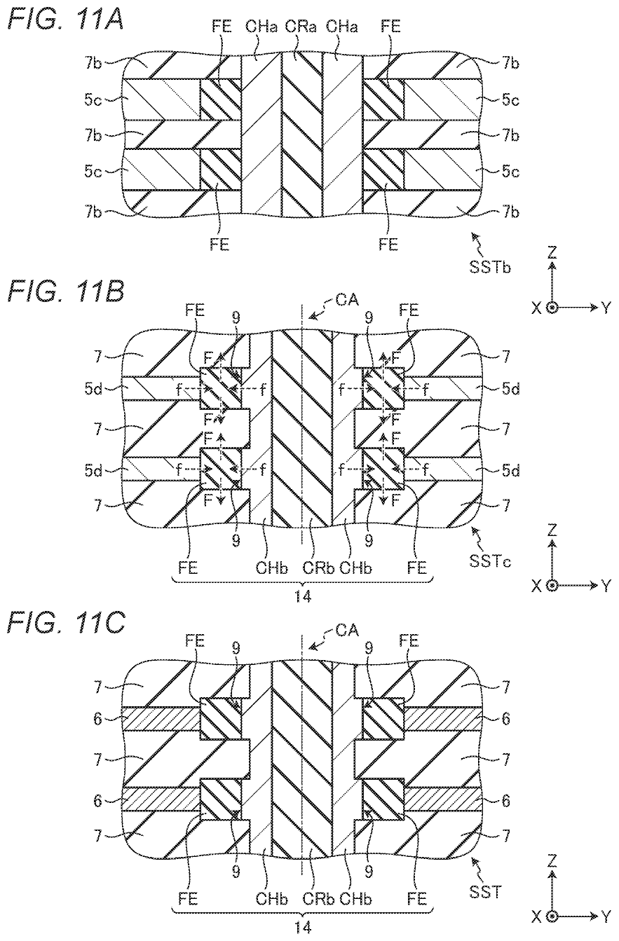

Also, as a modification of the first embodiment, the semiconductor memory device 1 may be manufactured under crystal orientation control such that compressive stress in the X and Y directions acts in addition to the Z direction tensile force F on the ferroelectric film FE. A method of manufacturing the semiconductor memory device 1 differs from that of the first embodiment in the following points, as shown in FIGS. 11A to 11C. Each of FIGS. 11A to 11C is a sectional view showing a method of manufacturing the semiconductor memory device 1.

After the processes shown in FIGS. 8A to 8C and 9A are carried out in the same way as in the first embodiment, a process shown in FIG. 11A is carried out.

In the process shown in FIG. 11A, a semiconductor is deposited on a side face and a bottom face of the memory hole 10c, whereby a semiconductor film CHa is formed. The semiconductor film CHa may be formed of a material having a semiconductor (for example, polysilicon) that substantially includes no impurity, as a main component. Further, an insulator is embedded on an inner side of the semiconductor film CHa in the memory hole 10c, whereby the core member CRa is formed. The core member CRa may be formed of an insulator such as silicon oxide.

In a process shown in FIG. 11B, the stacked body SSTb is thermally oxidized. By doing so, the ferroelectric film FE in the amorphous state is crystallized, changing to a polycrystalline state. Together with this, a portion of the semiconductor layer 5c in a vicinity of a face in contact with the insulating layer 7b is oxidized, whereby the semiconductor layer 5d is thinned and crystallized, together with which the insulating layer 7 is thickened.

At this time, each insulating layer 7 expands in the Z direction (refer to FIG. 10B). Because of this, the tensile force F in the Z direction acts on each ferroelectric film FE, as shown by a dotted arrow in FIG. 11B.

Also, each of a portion of the semiconductor film CHa in a vicinity of a face in contact with the core member CRa and a portion in a vicinity of a face in contact with the insulating layer 7b is oxidized, whereby a semiconductor film CHa is thinned and a semiconductor film CHb is formed, together with which a diameter of a core member CRb widens in the X and Y directions.

Because of this, the semiconductor film CHb having multiple protruding portions 9 on an outer side face is formed. The multiple protruding portions 9 are arranged to be separated from each other in the Z direction. Each protruding portion 9 has an approximate hollow disc shape centered on the central axis CA. The multiple protruding portions 9 respectively correspond to the multiple ferroelectric films FE. A Z position of each protruding portion 9 corresponds to a Z position of the ferroelectric film FE. For example, the Z position of each protruding portion 9 is approximately the same as the Z position of the ferroelectric film FE. A Z direction width of each protruding portion 9 corresponds to a Z direction width of the ferroelectric film FE. For example, the Z direction width of each protruding portion 9 is approximately equivalent to the Z direction width of the ferroelectric film FE.

The core member CRb, the semiconductor film CHb, and the multiple ferroelectric films FE are disposed in concentric circle form with respect to the central axis CA, whereby a columnar body 14 that penetrates the stacked body SSTc in the Z direction is formed.

At this time, the core member CRb expands in the X and Y directions. Because of this, a compressive stress f in the X and Y directions acts on each ferroelectric film FE, as indicated by a dotted arrow in FIG. 11B. The compressive stress f acts in a radial direction from the central axis CA in the XY plane on one side of the ferroelectric film FE, and a direction opposite to the radial direction on the other side of the ferroelectric film FE. The compressive stress f is applied by the semiconductor layer 5d in the direction opposite to the radial direction, and by the semiconductor film CHb in the radial direction.

Immediately after being crystallized, a direction of orientation of the multiple of crystals in the ferroelectric film FE is random.

As a result of the tensile force F applied to the ferroelectric film FE in the Z direction, a percentage of crystals whose direction of orientation is such that the a axis, which is the longest of the multiple of crystal axes (the a axis, the b axis, and the c axis), follows the direction of the tensile force F may increase. As a result, the percentage of crystals with the direction of orientation of FIGS. 6A and 6C may increase in comparison with the percentage of crystals with the direction of orientation of FIG. 6B.

As a result of the compressive stress f in the radial direction, a percentage of crystals whose direction of orientation is such that the b axis, which is the shortest of the multiple of crystal axes (the a axis, the b axis, and the c axis), follows the direction of the compressive stress f may increase. As a result, the percentage of crystals with the direction of orientation of FIG. 6A may increase in comparison with the percentage of crystals with the direction of orientation of FIG. 6C. Because of this, the percentage of crystals with the direction of orientation of FIG. 6A increases in the ferroelectric film FE, and the ferroelectric film FE as a whole further exhibits antiferroelectricity.

In a process shown in FIG. 11C, the semiconductor layer 5d is replaced by the conductive layer 6, and the stacked body SST in which the conductive layer 6 and the insulating layer 7 are alternately stacked repeatedly is formed. By doing so, the semiconductor memory device 1 is manufactured.

In this manufacturing method, the semiconductor memory device 1 can be manufactured while carrying out crystal orientation control such that the percentage of crystals exhibiting antiferroelectricity in the ferroelectric film FE in the initial state increases.

In this semiconductor memory device 1, the semiconductor film CHb has the multiple protruding portions 9 corresponding to the multiple ferroelectric films FE on the outer side face thereof. According to this structure, an electric field in a direction from the semiconductor film CHb toward the conductive layer 6 or an electric field in a direction from the conductive layer 6 toward the semiconductor film CHb may be generated easily. As a result, an electric field may be efficiently applied to the ferroelectric film FE when carrying out a write-erase operation with respect to the memory cell MT.

### Second Embodiment

Next, a semiconductor memory device according to a second embodiment will be described. Hereafter, a description will be given centered on portions differing from the first embodiment.

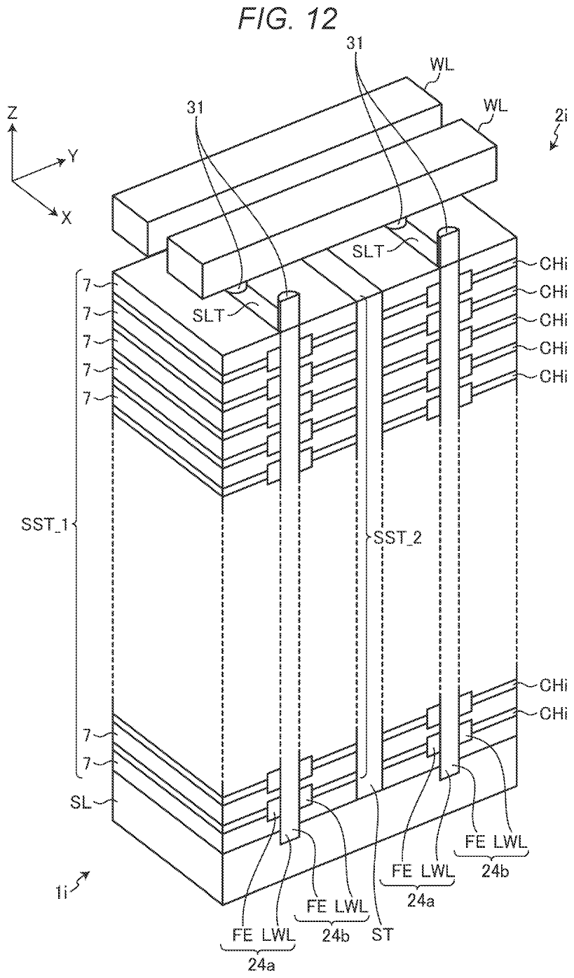

In the first embodiment, the three-dimensional memory cell array 2, in which a channel region (e.g., the semiconductor film CH) extends in the Z direction and a word line (e.g., the conductive layer 6) extends in the X and Y directions, is shown as an example, but in the second embodiment, a three-dimensional memory cell array 2i, in which a channel region (e.g., a semiconductor layer CHi) extends in the X and Y directions and a local word line (e.g., a conductive film LWL) extends in the Z direction, will be shown as an example. A semiconductor memory device 1i including the three-dimensional memory cell array 2i, in which the channel region extends in the X and Y directions and the local word line extends in the Z direction, may be configured as shown in FIG. 12. FIG. 12 is a perspective view showing a schematic configuration of the semiconductor memory device 1i according to the second embodiment.

As shown in FIG. 12, the semiconductor memory device 1i includes multiple dividing films SLT. The dividing film SLT may be formed of a material having an insulator (for example, silicon oxide) as a main component. The dividing films SLT are arranged in the X direction to fill spaces among a plurality of columnar conductive films LWL arranged in the X direction. Each dividing film SLT extends in the X and Z directions between the conductive films LWL. Because of this, the dividing films SLT divide the stacked body into a stacked body SST_1 on the −Y side and a stacked body SST_2 on the +Y side, and divide a columnar body into a columnar body 24a on the −Y side and a columnar body 24b on the +Y side.

The stacked body SST_1 is disposed on the −Y side of the conductive film LWL, and the stacked body SST_2 is disposed on the +Y side of the conductive film LWL. In each stacked body SST_1 and stacked body SST_2, a plurality of the semiconductor layers CHi are stacked alternately with a plurality of the insulating layers 7. The semiconductor layer CHi may be formed of a material having a semiconductor (for example, polysilicon) that substantially includes no impurity, as a main component.

On an end portion of the stacked body SST_1 on the +Y side, the columnar body 24a penetrates the stacked body SST_1 by extending in the Z direction, and on an end portion of the stacked body SST_2 on the −Y side, the columnar body 24b penetrates the stacked body SST_2 by extending in the Z direction. Each columnar body 24a and 24b has a plurality of protruding portions on side faces of the stacked body SST_1 and the stacked body SST_2. The protruding portions are arranged to be separated from each other in the Z direction. Each protruding portion has an approximate hollow disc shape centered on the central axis CA.

Each columnar body 24a and 24b includes the ferroelectric film FE and the conductive film LWL. The columnar body 24a and the columnar body 24b aligned with each other in the X and Y directions may share the same conductive film LWL. In each columnar body 24a and 24b, the ferroelectric film FE is disposed in a Z position corresponding to the semiconductor layer CHi. The ferroelectric film FE may be formed of a material having a ferroelectric body as a main component. The conductive film LWL may be formed of a material having a metal such as tungsten as a main component. The conductive film LWL is connected to the conductive layer 3, which functions as the source line SL, on the −Z side, and is connected to the conductive layer 9, which functions as the word line WL, via the contact plug 31 on the +Z side. Each group of the conductive films LWL that are connected to the same word line WL, functions as a local word line.

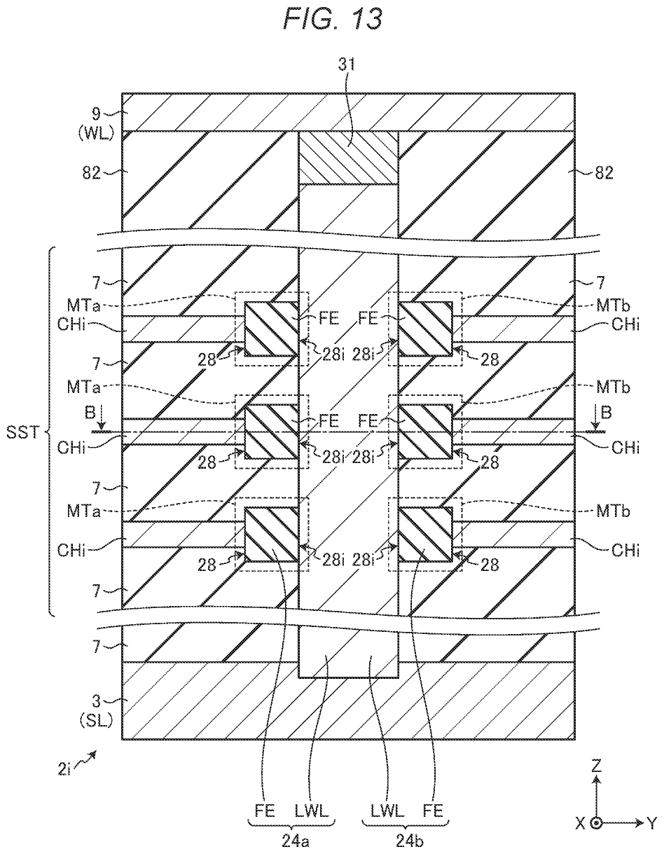

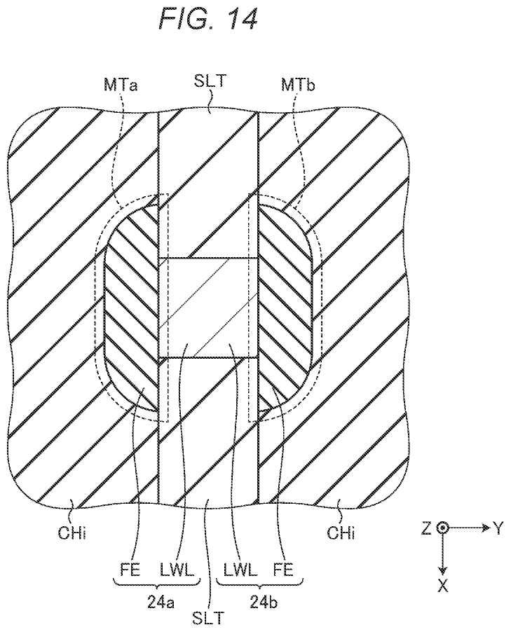

With this structure, the dividing film SLT divides the memory cells MT into memory cells MTa and memory cells MTb, as shown in FIGS. 13 and 14. With this structure of the semiconductor memory device 1i, a distribution density of the memory cells MTa and MTb can easily be increased. FIG. 13 is a sectional view in the YZ plane showing a configuration of the memory cell array 2i. FIG. 14 is a sectional view in the XY plane showing a configuration of the memory cells MTa and MTb. FIG. 14 is a sectional view of a cross-section that is cut in the X and Y directions along the B-B line in FIG. 13.

The memory cell MTa is provided at a location where the semiconductor layer CHi of the stacked body SST_1 and the conductive film LWL intersect. The memory cell MTb is provided at a location where the semiconductor layer CHi of the stacked body SST_2 and the conductive film LWL intersect.

Herein, a thickness of the ferroelectric film FE in the stacking direction in the intersection positions in which the memory cells MTa and MTb are provided is greater than a thickness of the semiconductor layer CHi in the stacking direction. This structure is manufactured under crystal orientation control that increases the percentage of crystals exhibiting antiferroelectricity, and is a structure in which the percentage of crystals exhibiting antiferroelectricity in the ferroelectric film FE increases in the initial state. A structure in which the percentage of crystals exhibiting antiferroelectricity in the ferroelectric film FE increases in the initial state can suppress a deterioration in write properties corresponding to an increase in the number of write-erase cycles in comparison with a structure in which the percentage of crystals exhibiting ferroelectricity in the ferroelectric film FE increases in the initial state (refer to (a) and (b) of FIG. 7), so that endurance properties can be improved.

That is, a structure that can increase an operational reliability of the semiconductor memory device 1i is a structure in which the thickness of the ferroelectric film FE in the stacking direction is greater than the thickness of the semiconductor layer CHi in the stacking direction at the intersection positions in which the memory cells MTa and MTb are provided.

Also, as shown in FIG. 13, a side face 28 on the semiconductor layer CHi side of the ferroelectric film FE is flat in the stacking direction (the Z direction). A side face 28i on the conductive film LWL side of the ferroelectric film FE is also flat in the stacking direction (the Z direction). With this structure, the voltage E is applied in a direction from the semiconductor layer CHi toward the conductive film LWL, or in a direction from the conductive film LWL toward the semiconductor layer CHi, an electric field concentration on the side faces 28 and 28i is less likely to develop, and a comparatively uniform electric field can be applied to the ferroelectric film FE. Because of this, a polarized charge can be efficiently generated on the inner side face 28i and the outer side face 28 of the ferroelectric film FE. As a result, the operational reliability of the semiconductor memory device 1i can be increased.

The method of manufacturing the semiconductor memory device 1i is the same as the manufacturing method shown in FIGS. 8A to 8C, 9A to 9C, and 10A to 10B, except as follows. First, the semiconductor layer 5d is a conductive layer that is not replaced. In this case, the semiconductor layer 5d may be formed of a material having a semiconductor that includes an impurity and to which conductivity is imparted (for example, an n-type polysilicon including a donor impurity or a p-type polysilicon including an acceptor impurity) as a main component in the process shown in FIG. 8A. Therefore, the removal of the semiconductor layer 5d and the embedding of the conductive layer 6 shown in FIG. 9C are omitted. In addition, the conductive film LWL (refer to FIG. 13) is embedded in the memory hole 10c instead of the semiconductor film CH and the core member CR.

In the semiconductor memory device 1i according to the second embodiment, the memory cell MT is provided at a location where the semiconductor layer CHi and the conductive film LWL in the stacked body SST intersect across the ferroelectric film FE. The thickness of the ferroelectric film FE in the stacking direction at the intersection position is greater than the thickness of the semiconductor layer CHi in the stacking direction. This structure is manufactured under crystal orientation control such that the Z direction tensile force F acts on the ferroelectric film FE, and is a structure in which the percentage of crystals exhibiting antiferroelectricity in the ferroelectric film FE increases in the initial state. That is, an increase in the operational reliability of the semiconductor memory device 1i can be provided using a structure in which the thickness of the ferroelectric film FE in the stacking direction at an intersection position where the memory cell MT is provided, is greater than the thickness of the semiconductor layer CHi in the stacking direction.

Also, in the semiconductor memory device 1i of the second embodiment, the side face 28 on the semiconductor layer CHi side of the ferroelectric film FE is flat in the stacking direction, and the side face 28i on the conductive film LWL side of the ferroelectric film FE is flat in the stacking direction. With this structure, when the voltage E is applied in a direction from the semiconductor layer CHi toward the conductive film LWL, or in a direction from the conductive film LWL toward the semiconductor layer CHi, an electric field concentration on the side faces 28 and 28i is less likely to develop, and a comparatively uniform electric field can be applied to the ferroelectric film FE. Because of this, a polarized charge can be efficiently generated on the inner side face 28i and the outer side face 28 of the ferroelectric film FE. As a result, the operational reliability of the semiconductor memory device 1i can be increased.

### Third Embodiment

Next, a semiconductor memory device according to a third embodiment will be described. Hereafter, a description will be given centered on portions differing from the first embodiment and the second embodiment.

In the first embodiment, a structure in which the outer side face of the semiconductor film CH is flat in the stacking direction is shown as an example, but in the third embodiment, a structure in which an outer side face of a semiconductor film CHc has a recessed portion in a Z position corresponding to the ferroelectric film FE will be shown as an example.

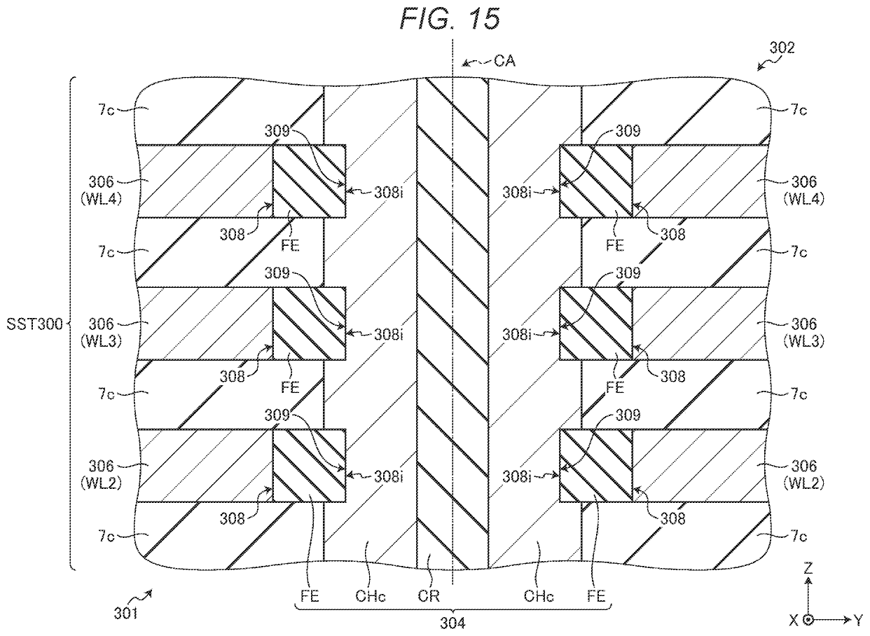

A memory cell array 302 in a semiconductor memory device 301 has a structure shown in FIG. 15 that differs from the first embodiment in the following points. FIG. 15 is a sectional view showing a configuration of the memory cell array 302 in the third embodiment.

The semiconductor memory device 301 has a plurality of columnar bodies 304 and a stacked body SST300 instead of the multiple of columnar bodies 4 and the stacked body SST in the first embodiment (refer to FIG. 4).

Each columnar body 304 has the semiconductor film CHc instead of the semiconductor film CH in the first embodiment (refer to FIG. 4). The semiconductor film CHc has a plurality of recessed portions 309 in an outer side face thereof. The recessed portions 309 are arranged to be separated from each other in the Z direction. Each recessed portion 309 has an approximate hollow disc shape centered on the central axis CA. The multiple recessed portions 309 respectively correspond to the multiple ferroelectric films FE. A Z position of each recessed portion 309 corresponds to a Z position of the ferroelectric film FE. For example, the Z position of each recessed portion 309 is approximately the same as the Z position of the ferroelectric film FE. A Z direction width of each recessed portion 309 corresponds to a Z direction width of the ferroelectric film FE. For example, the Z direction width of each recessed portion 309 is approximately equivalent to the Z direction width of the ferroelectric film FE.

In the stacked body SST300, a conductive layer 306 and an insulating layer 7c are alternately stacked repeatedly. In the stacked body SST300, a thickness of the ferroelectric film FE in the stacking direction (the Z direction) is approximately equivalent to a thickness of the conductive layer 306 in the stacking direction at a location where the conductive layer 306 and the semiconductor film CHc intersect across the ferroelectric film FE.

As shown in FIG. 15, a side face 308 on the conductive layer 306 side of the ferroelectric film FE is flat in the stacking direction (the Z direction). A side face 308i on the semiconductor film CHc side of the ferroelectric film FE is flat in the stacking direction (the Z direction). With this structure, when the voltage E is applied in a direction from the semiconductor film CHc toward the conductive layer 306, or in a direction from the conductive layer 306 toward the semiconductor film CHc, an electric field concentration in the side faces 308 and 308i is less likely to develop, and a comparatively uniform electric field can be applied to the ferroelectric film FE. Because of this, a polarized charge can be efficiently generated on the inner side face 308i and the outer side face 308 of the ferroelectric film FE. As a result, an operational reliability of the semiconductor memory device 301 can be increased.

In the semiconductor memory device 301, the semiconductor film CHc has the multiple recessed portions 309 respectively corresponding to the multiple ferroelectric films FE on the outer side face thereof. According to this structure, an electric field in a direction from the semiconductor film CHc toward the conductive layer 306 or an electric field in a direction from the conductive layer 306 toward the semiconductor film CHc may be generated easily. As a result, an electric field may be efficiently applied to the ferroelectric film FE when carrying out a write-erase operation with respect to the memory cell MT.

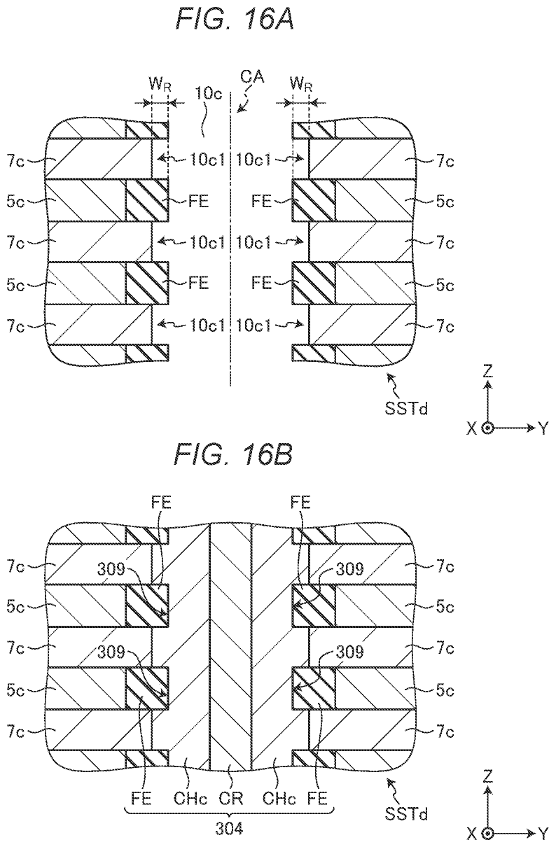

Also, a method of manufacturing the semiconductor memory device 301 differs from that of the first embodiment in the following points. FIGS. 16A and 16B are sectional views showing a method of manufacturing the semiconductor memory device 301. FIG. 15 is a sectional view showing a configuration of the memory cell array 302, but will also be used as a sectional view illustrating a method of manufacturing the semiconductor memory device 301.

In the third embodiment, after the processes shown in FIGS. 8A to 8C and FIG. 9A are carried out, a process shown in FIG. 16A is carried out.

In the process shown in FIG. 16A, an insulating layer recessing process is carried out, causing a side face of the insulating layer 7c exposed in the memory hole 10c to recede by etching. A recessed portion 10cl is formed in an inner side face of the memory hole 10c by the insulating layer recessing process. The recessed portion 10cl is formed in a Z position of the insulating layer 7c in a stacked body SSTd in such a way as to be recessed from the inner side face of the memory hole 10c in a direction away from the central axis CA of the memory hole 10c. For example, a wet etching is carried out on the inner side face of the memory hole 10c using an etchant such that an etch selectivity of the insulating layer 7c with respect to that of the ferroelectric film FE is high. Alternatively, a dry etching is carried out on the inner side face of the memory hole 10c under conditions of an isotropic etching using a processing gas such that an etch selectivity of the insulating layer 7c with respect to that of the ferroelectric film FE is high.

By doing so, a side face of the insulating layer 7c exposed in the memory hole 10c is caused to recede by etching, whereby the recessed portion 10cl can be formed in the inner side face of the memory hole 10c. A width of recession of the recessed portion 10cl with respect to the inner side face of the memory hole 10c may be regulated by the etching time. A width of recession represents a depth of the recessed portion 10cl in a radial direction from the central axis CA approximately in the XY plane. The recession width is a recession width caused by the recessing process, and is called an insulating layer recession amount W_{R}. A width in the Z direction of the recessed portion 10cl is approximately equivalent to a film thickness of the insulating layer 7c.

In a process shown in FIG. 16B, the stacked body SSTd is thermally oxidized. By doing so, the ferroelectric film FE in the amorphous state is crystallized, changing to a polycrystalline state.

Subsequently, a semiconductor is deposited on the side face and the bottom face of the memory hole 10c, whereby the semiconductor film CHc is formed. The semiconductor film CHc may be formed of a material having a semiconductor (for example, polysilicon) that substantially includes no impurity, as a main component.

Because of this, the semiconductor film CHc having the multiple recessed portions 309 in the outer side face thereof is formed. The recessed portions 309 are arranged to be separated from each other in the Z direction. Each recessed portion 309 has an approximate hollow disc shape centered on the central axis CA. The multiple recessed portions 309 respectively correspond to the multiple ferroelectric films FE. A Z position of each recessed portion 309 corresponds to a Z position of the ferroelectric film FE. For example, the Z position of each recessed portion 309 is approximately the same as the Z position of the ferroelectric film FE. A Z direction width of each recessed portion 309 corresponds to a Z direction width of the ferroelectric film FE. For example, the Z direction width of each recessed portion 309 is approximately equivalent to the Z direction width of the ferroelectric film FE.

An insulator is embedded on an inner side of the semiconductor film CHc in the memory hole 10c, whereby the core member CR is formed. The core member CR may be formed of an insulator such as silicon oxide.

The core member CR, the semiconductor film CHc, and the ferroelectric films FE are disposed in concentric circle form with respect to the central axis CA, whereby the columnar body 304 that penetrates the stacked body SSTd in the Z direction is formed.

In a process for manufacturing the semiconductor memory device 301 shown in FIG. 15, the semiconductor layer 5b is replaced by the conductive layer 306, such that the stacked body SST300 including the conductive layer 306 and the insulating layer 7c that are alternately stacked repeatedly, is formed. By doing so, the semiconductor memory device 301 is manufactured.

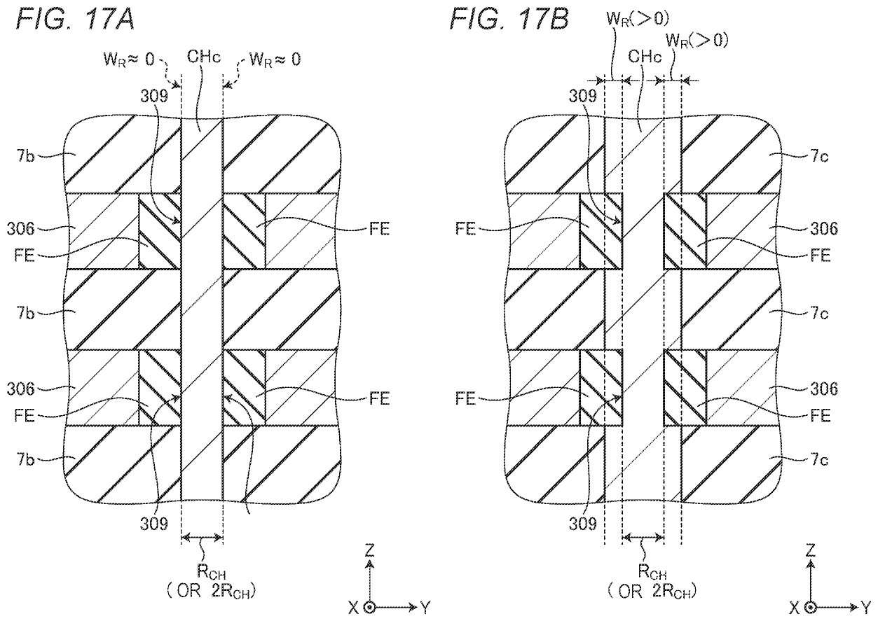

Next, a relationship between the insulating layer recession amount W_{R} in the process shown in FIG. 16A and an operating voltage of the memory cell MT will be described. The insulating layer recession amount W_{R} may vary as shown in FIGS. 17A and 17B. FIGS. 17A and 17B are drawings showing the insulating layer recession amount W_{R}.

When the insulating layer recessing process is not carried out as shown in FIG. 17A, and so the recession width of the recessed portion 10cl from the inner side face of the memory hole 10c is substantially zero, the semiconductor film CHc is formed in the memory hole 10c having a diameter R_{CH} (or 2R_{CH}), such that the depth of the recessed portion 309 on the outer side face of the semiconductor film CHc is substantially zero. In this case, the insulating layer recession amount W_{R} is approximately equal to zero, as shown in FIG. 17A.

When the insulating layer recessing process is carried out as shown in FIG. 17B, and the recession width of the recessed portion 10cl from the inner side face of the memory hole 10c is, for example, W_{R}, the semiconductor film CHc is formed in the memory hole 10c having a diameter R_{CH} (or 2R_{CH}), such that the depth of the recessed portion 309 on the outer side face of the semiconductor film CHc is W. In this case, the insulating layer recession amount W_{R} equals W, as shown in FIG. 17B.

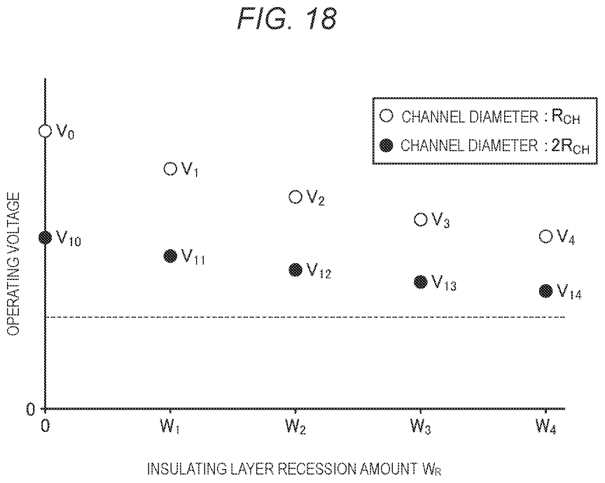

With regard to the memory cell MT in a state in which the ferroelectric film FE exhibits ferroelectricity (a woken-up state), a change in operating voltage when the insulating layer recession amount W_{R} is changed as shown in FIGS. 17A and 17B is simulated. Results thereof are shown in FIG. 18. FIG. 18 is a drawing showing a relationship between the insulating layer recession amount W_{R} of four different values, W₁, W₂, W₃, and W₄, and the operating voltage of the memory cell MT. In FIG. 18, a vertical axis shows the operating voltage of the memory cell MT, and a horizontal axis shows the insulating layer recession amount W_{R}.

The operating voltage of the memory cell MT is a voltage for a polarity of a polarized charge to be inverted, so that “1” is written, from an erasure state in which the memory cell MT holds “0”, as indicated by a solid line in (b) of FIG. 7. The operating voltage of the memory cell MT corresponds to a voltage V_{R} shown in (b) of FIG. 7.

When the diameter of the semiconductor film CHc is R_{CH}, as indicated by a white circle in FIG. 18, the operating voltage V_{R} of the memory cell MT decreases from V₀ to V₁ (<V₀), to V₂ (<V₁), to V₃ (<V₂), and then to V₄ (<V₃) as the insulating layer recession amount W_{R} increases from zero to W_{R}=W₁, to W_{R}=W₂, to W_{R}=W₃, and then to W_{R}=W₄.

When the diameter of the semiconductor film CHc is 2R_{CH}, as indicated by a black circle in FIG. 18, the operating voltage of the memory cell MT decreases from V₁₀ to V₁₁ (<V₁₀), to V₁₂ (<V₁₁), to V₁₃ (<V₁₂), and then to V₁₄ (<V₁₃) as the insulating layer recession amount W_{R} increases from zero to W_{R}=W₁, to W_{R}=W₂, to W_{R}=W₃, and then to W_{R}=W₄.

When the insulating layer recession amount is such that W_{R} is approximately equal to zero, and the diameter of the semiconductor film CHc changes from R_{CH} to 2R_{CH}, the operating voltage of the memory cell MT decreases from V_{R}=V₀ to V_{R}=V₁₀ (<V₀). When the insulating layer recession amount is such that W_{R}=W₄, and the diameter of the semiconductor film CHc changes from R_{CH} to 2R_{CH}, the operating voltage of the memory cell MT decreases from V_{R}=V₄ to V_{R}=V₁₄ (<V₄).

From the simulation results shown in FIG. 18, it is confirmed that the greater the X and Y direction depth (approximately equal to the insulating layer recession amount W_{R}) of the recessed portion 309 on the outer side face of the semiconductor film CHc, the more the operating voltage of the memory cell MT can be reduced.

In the semiconductor memory device 301 of the third embodiment, the semiconductor film CHc has the multiple recessed portions 309 respectively corresponding to the multiple ferroelectric films FE on the outer side face thereof. According to this structure, an electric field in a direction from the semiconductor film CHc toward the conductive layer 306 or an electric field in a direction from the conductive layer 306 toward the semiconductor film CHc may be generated easily. As a result, an electric field may be efficiently applied to the ferroelectric film FE when carrying out a write-erase operation with respect to the memory cell MT.

### Fourth Embodiment

Next, a semiconductor memory device according to a fourth embodiment will be described. Hereafter, a description will be given centered on portions differing from the first to third embodiments.

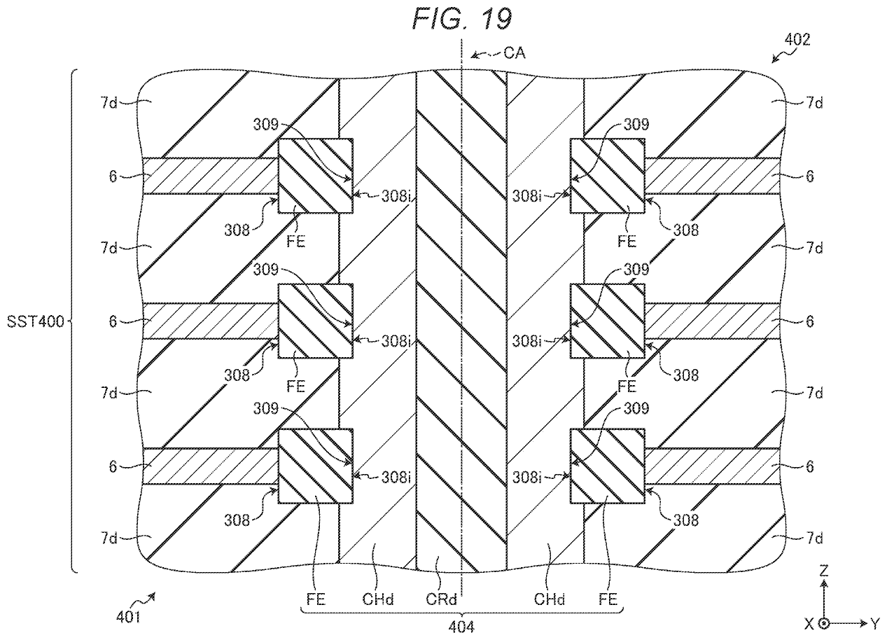

The fourth embodiment combines the features of the first to third embodiments. A memory cell array 402 in a semiconductor memory device 401 of the fourth embodiment, shown in FIG. 19, has a configuration that differs from the first embodiment in the following points. FIG. 19 is a sectional view showing a configuration of the memory cell array 402 in the fourth embodiment.

The semiconductor memory device 401 has columnar bodies 404 and a stacked body SST400 instead of the columnar bodies 4 and the stacked body SST (refer to FIG. 4).

Each columnar body 404 is obtained by increasing the diameter of the core member CR in each columnar body 304 (refer to FIG. 15) to obtain a core member CRd, and thinning the semiconductor film CHc to obtain a semiconductor film CHd.

In the stacked body SST400, the conductive layer 6 and the insulating layer 7d are alternately stacked repeatedly. In the stacked body SST400, a thickness of the ferroelectric film FE in the stacking direction (the Z direction) is greater than a thickness of the conductive layer 6 in the stacking direction at a location where the conductive layer 6 and the semiconductor film CHd intersect across the ferroelectric film FE. This structure is manufactured under crystal orientation control that increases the percentage of crystals exhibiting antiferroelectricity, and is a structure in which the percentage of crystals exhibiting antiferroelectricity in the ferroelectric film FE increases in the initial state. A structure in which the percentage of crystals exhibiting antiferroelectricity in the ferroelectric film FE increases in the initial state can suppress a deterioration in write properties corresponding to an increase in the number of write-erase cycles in comparison with a structure in which the percentage of crystals exhibiting ferroelectricity in the ferroelectric film FE increases in the initial state (refer to (a) and (b) of FIG. 7), so that endurance properties can be improved.

That is, a structure that can increase an operational reliability of the semiconductor memory device 401 is a structure in which the thickness of the ferroelectric film FE in the stacking direction is greater than the thickness of the conductive layer 6 in the stacking direction at the intersection position where the memory cell MT is provided.

As shown in FIG. 19, the side face 308 on the conductive layer 6 side of the ferroelectric film FE is flat in the stacking direction (the Z direction). The side face 308i on the semiconductor film CHd side of the ferroelectric film FE is also flat in the stacking direction (the Z direction). With this structure, when the voltage E is applied in a direction from the semiconductor film CHd toward the conductive layer 6, or in a direction from the conductive layer 6 toward the semiconductor film CHd, an electric field concentration on the side faces 308 and 308i is less likely to develop, and a comparatively uniform electric field can be applied to the ferroelectric film FE. Because of this, a polarized charge can be efficiently generated on the inner side face 308i and the outer side face 308 of the ferroelectric film FE. As a result, the operational reliability of the semiconductor memory device 401 can be increased.

In the semiconductor memory device 401, the semiconductor film CHd has the multiple recessed portions 309 respectively corresponding to the multiple ferroelectric films FE on an outer side face thereof. According to this structure, an electric field in a direction from the semiconductor film CHd toward the conductive layer 6 or an electric field in a direction from the conductive layer 6 toward the semiconductor film CHd may be generated easily. As a result, an electric field may be efficiently applied to the ferroelectric film FE when carrying out a write-erase operation with respect to the memory cell MT.

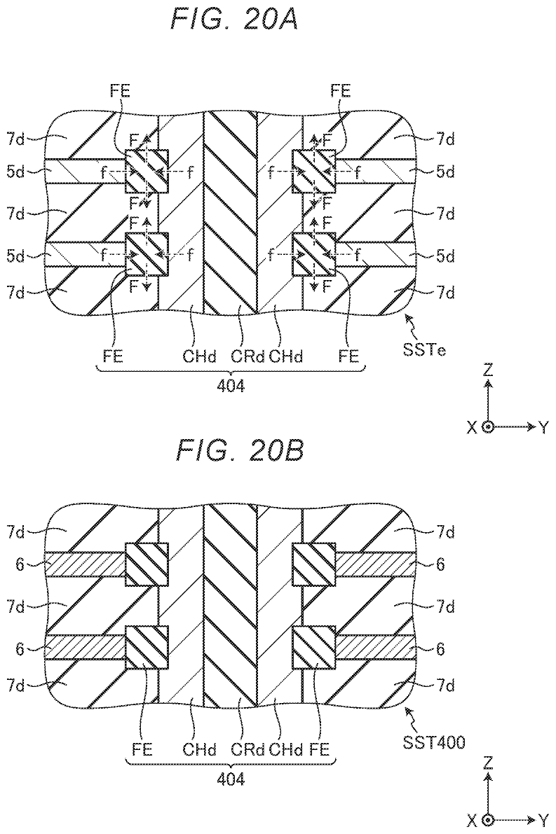

Also, a method of manufacturing the semiconductor memory device 401 differs from that of the first embodiment in the following points. FIGS. 20A and 20B are sectional views showing a method of manufacturing the semiconductor memory device 401. FIG. 19 is a sectional view showing a configuration of the memory cell array 402, and will also be used as a sectional view illustrating a method of manufacturing the semiconductor memory device 401.

In the fourth embodiment, after the processes shown in FIGS. 8A to 8C, FIG. 9A, and FIGS. 16A and 16B are carried out, a process shown in FIG. 20A is carried out.

In the process shown in FIG. 20A, the stacked body SSTe is thermally oxidized. By doing so, the ferroelectric film FE in the amorphous state is crystallized, changing to a polycrystalline state. Together with this, a portion of the semiconductor layer 5c in a vicinity of a face in contact with the insulating layer 7b is oxidized, whereby the semiconductor layer 5c is thinned and crystallized (to become the semiconductor layer 5d), and the insulating layer 7d is thickened.

At this time, each insulating layer 7d expands in the Z direction (refer to FIG. 10B). Because of this, the tensile force F in the Z direction acts on each ferroelectric film FE, as shown by a dotted arrow in FIG. 20A.

Also, each of a portion of the semiconductor film CHc in a vicinity of a face in contact with the core member CR and a portion in a vicinity of a face in contact with the insulating layer 7d is oxidized, whereby the semiconductor film CHd is thinned, and a diameter of the core member CRd widens in the X and Y directions.

Because of this, the semiconductor film CHd having the multiple recessed portions 309 on an outer side face is formed. The recessed portions 309 are arranged to be separated from each other in the Z direction. Each recessed portion 309 has an approximate hollow disc shape centered on the central axis CA. The multiple recessed portions 309 respectively correspond to the multiple ferroelectric films FE. A Z position of each recessed portion 309 corresponds to a Z position of the ferroelectric film FE. For example, the Z position of each recessed portion 309 is approximately the same as the Z position of the ferroelectric film FE. A Z direction width of each recessed portion 309 corresponds to a Z direction width of the ferroelectric film FE. For example, the Z direction width of each recessed portion 309 is approximately equivalent to the Z direction width of the ferroelectric film FE.

The core member CRd, the semiconductor film CHd, and the ferroelectric films FE are disposed in concentric circle form with respect to the central axis CA, whereby the columnar body 404 that penetrates a stacked body SSTe in the Z direction is formed.

Because the core member CRd expands in the X and Y directions, the compressive stress f in the X and Y directions acts on each ferroelectric film FE, as indicated by a dotted arrow in FIG. 20A. The compressive stress f acts in a radial direction from the central axis CA in the XY plane on one side of the ferroelectric film FE, and a direction opposite to the radial direction on the other side of the ferroelectric film FE. The compressive stress f is applied by the semiconductor layer 5d in the direction opposite to the radial direction, and by the semiconductor film CHd in the radial direction.

Immediately after being crystallized, a direction of orientation of the multiple of crystals in the ferroelectric film FE is random.

As a result of the tensile force F applied to the ferroelectric film FE in the Z direction, a percentage of crystals whose direction of orientation is such that the a axis, which is the longest of the multiple of crystal axes (the a axis, the b axis, and the c axis), follows the direction of the tensile force F may increase. As a result, the percentage of crystals with the direction of orientation of FIGS. 6A and 6C may increase in comparison with the percentage of crystals with the direction of orientation of FIG. 6B.

As a result of the compressive stress f in the radial direction, a percentage of crystals whose direction of orientation is such that the b axis, which is the shortest of the multiple of crystal axes (the a axis, the b axis, and the c axis), follows the direction of the compressive stress f may increase. As a result, the percentage of crystals with the direction of orientation of FIG. 6A may increase in comparison with the percentage of crystals with the direction of orientation of FIG. 6C. Because of this, the percentage of crystals with the direction of orientation of FIG. 6A increases in the ferroelectric film FE, and the ferroelectric film FE as a whole further exhibits antiferroelectricity.

In a process shown in FIG. 20B, the semiconductor layer 5d is replaced by the conductive layer 6, and the stacked body SST400 in which the conductive layer 6 and the insulating layer 7d are alternately stacked repeatedly is formed, as shown in FIG. 19. By doing so, the semiconductor memory device 401 is manufactured.

In the semiconductor memory device 401 of the fourth embodiment, the memory cell MT is provided at a location where the conductive layer 6 and the semiconductor film CHd in the stacked body SST400 intersect across the ferroelectric film FE. The thickness of the ferroelectric film FE in the stacking direction at the intersection position is greater than the thickness of the conductive layer 6 in the stacking direction. This structure is manufactured under crystal orientation control such that the Z direction tensile force Facts on the ferroelectric film FE, and is a structure in which the percentage of crystals exhibiting antiferroelectricity in the ferroelectric film FE increases in the initial state. That is, a structure that can increase the operational reliability of the semiconductor memory device 401 is a structure in which the thickness of the ferroelectric film FE in the stacking direction at an intersection position where the memory cell MT is provided is greater than the thickness of the conductive layer 6 in the stacking direction.

Also, in the semiconductor memory device 401 of the fourth embodiment, the side face 308 on the conductive layer 6 side of the ferroelectric film FE is flat in the stacking direction, and the side face 308i on the semiconductor film CHd side of the ferroelectric film FE is also flat in the stacking direction. With this structure, when the voltage E is applied in a direction from the semiconductor film CHd toward the conductive layer 6, or in a direction from the conductive layer 6 toward the semiconductor film CHd, an electric field concentration on the side faces 308 and 308i is less likely to develop, and a comparatively uniform electric field can be applied to the ferroelectric film FE. Because of this, a polarized charge can be efficiently generated on the inner side face 308i and the outer side face 308 of the ferroelectric film FE. As result, an operational reliability of the semiconductor memory device 401 can be increased.

Also, in the semiconductor memory device 401 of the fourth embodiment, the semiconductor film CHd has the multiple recessed portions 309 respectively corresponding to the multiple ferroelectric films FE on an outer side face thereof. According to this structure, an electric field in a direction from the semiconductor film CHd toward the conductive layer 6 or an electric field in a direction from the conductive layer 6 toward the semiconductor film CHd may be generated easily. As a result, an electric field may be efficiently applied to the ferroelectric film FE when carrying out a write-erase operation with respect to the memory cell MT.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a stacked body in which a plurality of electrode layers and a plurality of insulating layers are alternately stacked in a first direction;
an electrode film that extends in the stacked body in the first direction; and
a plurality of ferroelectric films, each of which is disposed between and in contact with one of the electrode layers and the electrode film, wherein
each of the ferroelectric films has a thickness in the first direction that is greater than the electrode layer that is in contact therewith.

2. The semiconductor memory device according to claim 1, wherein a side face of each of the ferroelectric films in contact with the corresponding electrode layer is flat in the flat direction.

3. The semiconductor memory device according to claim 2, wherein a side face of each of the ferroelectric films in contact with the electrode film is flat in the first direction.

4. The semiconductor memory device according to claim 1, wherein the electrode film is an undoped semiconductor film, and the electrode layer is a conductive layer.

5. The semiconductor memory device according to claim 1, wherein the electrode film is a conductive film, and the electrode layer is an undoped semiconductor layer.

6. The semiconductor memory device according to claim 1, wherein each of the ferroelectric films exhibits antiferroelectricity in an initial state.

7. The semiconductor memory device according to claim 1, wherein
each of the ferroelectric films includes a plurality of crystals, each having a polarizing axis, and in an initial state thereof, has a smaller percentage of the crystals that have polarizing axes that are generally aligned with a direction from the electrode layer toward the electrode film than those that are generally perpendicular to the direction.

8. The semiconductor memory device according to claim 7, wherein each of the crystals has a first crystal axis, a second crystal axis that is shorter than the first crystal axis, and a third crystal axis that is shorter than the first crystal axis and longer than the second crystal axis and functions as the polarizing axis.

9. The semiconductor memory device according to claim 1, wherein the ferroelectric films are formed of a material having hafnium oxide as a main component.

10. The semiconductor memory device according to claim 9, wherein the ferroelectric films are formed of a material further including at least one element selected from a group including silicon (Si), scandium (Sc), yttrium (Y), titanium (Ti), vanadium (V), niobium (Nb), tantalum (Ta), zirconium (Zr), aluminum (Al), strontium (Sr), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), and lutetium (Lu).

11. The semiconductor memory device according to claim 1, wherein an outer side face of the electrode film has a plurality of protruding portions at locations corresponding to the plurality of ferroelectric films.

12. The semiconductor memory device according to claim 1, wherein an outer side face of the electrode film has a plurality of recessed portions corresponding to the plurality of ferroelectric films.

13. A semiconductor memory device, comprising:
a stacked body in which a plurality of electrode layers and a plurality of insulating layers are alternately stacked in a first direction;
a pillar having an electrode film on an outer periphery thereof that extends in the stacked body in the first direction; and
a plurality of ferroelectric memory cells at intersections of the electrode film and the electrode layers, each of the ferroelectric memory cells including a semiconductor channel, a conductive layer, and a ferroelectric film between and in contact with the semiconductor channel and the conductive layer, wherein one of the semiconductor channel and the conductive layer is formed from a part of the electrode film and the other one of the semiconductor channel and the conductive layer is formed from a part of the electrode layers, wherein
the ferroelectric film of each of the ferroelectric memory cells has a thickness in the first direction that is greater than the electrode layer that is in contact therewith.

14. The semiconductor memory device according to claim 13, wherein the ferroelectric film in each of the ferroelectric memory cells has a first surface in contact with the semiconductor channel that is flat in the first direction and a second surface in contact with the conductive layer that is flat in the first direction.

15. The semiconductor memory device according to claim 13, wherein an outer side face of the electrode film has a plurality of protruding portions at locations corresponding to the plurality of ferroelectric memory cells.

16. The semiconductor memory device according to claim 13, wherein an outer side face of the electrode film has a plurality of recessed portions corresponding to the plurality of ferroelectric memory cells.

17. The semiconductor memory device according to claim 13, wherein the ferroelectric film in each of the ferroelectric memory cells exhibits antiferroelectricity in an initial state.

18. A semiconductor memory device manufacturing method, comprising:
stacking a plurality of semiconductor layers and a plurality of insulating layers alternately in a first direction to form a stacked body;
forming a hole in the stacked body that extends in the first direction;
etching an end face of each of the semiconductor layers exposed in the hole to form a plurality of first recessed portions in an inner side face of the hole;
depositing a ferroelectric body in the first recessed portions to form a plurality of ferroelectric films; and
oxidizing a portion of each of the semiconductor layers in contact with the insulating layer to thicken the insulating layer and thin the semiconductor layer.

19. The semiconductor memory device manufacturing method according to claim 18, further comprising:
prior to said oxidizing, forming a semiconductor on a side face and a bottom face of the hole, and an insulator along a center axis of the hole, wherein
the semiconductor on the side face is in contact with the ferroelectric films and the insulating layers, and
during said oxidizing, a portion of the semiconductor in contact with the core member is oxidized, thereby widening a diameter of the insulator, and thinning the semiconductor.

20. The semiconductor memory device manufacturing method according to claim 18, further comprising:
after forming the ferroelectric films, etching the insulating layers exposed in the hole to form a plurality of second recessed portions that are recessed with respect to side surfaces of the ferroelectric films; and
forming a semiconductor on a side face and a bottom face of the hole, and an insulator along a center axis of the hole, wherein the semiconductor formed on the side face of the hole fills up the second recessed portions.
